(19) United States
(12) Patent Application Publication
(10) Pub. No.: US 2017/0213872 A1
(43) Pub. Date: Jul. 27, 2017

(54) DISPLAY DEVICE

(71) Applicant: Semiconductor Energy Laboratory Co., Ltd., Atsugi-shi (JP)

(72) Inventors: Yasuhiro JINBO, Isehara (JP); Kohei YOKOYAMA, Fujisawa (JP); Yuji IWAKI, Isehara (JP); Minato ITO, Isehara (JP); Taisuke KAMADA, Toda (JP)

(73) Assignee: Semiconductor Energy Laboratory Co., Ltd.

(21) Appl. No.: 15/404,459

(22) Filed: Jan. 12, 2017

(30) Foreign Application Priority Data
Jan. 27, 2016 (JP) 2016-013331

(51) Int. Cl. H01L 27/32; H01L 51/00; H01L 51/52

(52) U.S. Cl. CPC H01L 27/322; H01L 27/323; H01L 51/5284; H01L 51/0097; H01L 2251/5338; H01L 2227/323

(57) ABSTRACT

To provide a display device with high reliability. To provide a repeatedly bendable flexible display. A first substrate, a second substrate, a display element, a light-blocking layer, a first barrier layer, and an adhesive layer are included. The first substrate and the second substrate face each other. The display element, the light-blocking layer, the first barrier layer, and the adhesive layer are between the first substrate and the second substrate. The display element is between the first substrate and the adhesive layer. The light-blocking layer is between the second substrate and the adhesive layer. The first barrier layer includes a region between the light-blocking layer and the adhesive layer. The first barrier layer includes a material having a higher Young's modulus than the light-blocking layer or the adhesive layer.

### BACKGROUND OF THE INVENTION

1. Field of the Invention

One embodiment of the present invention relates to a display device. One embodiment of the present invention relates to a flexible display device.

Note that one embodiment of the present invention is not limited to the above technical field. Examples of the technical field of one embodiment of the present invention disclosed in this specification and the like include a semiconductor device, a display device, a light-emitting device, a power storage device, a memory device, an electronic device, a lighting device, an input device, an input/output device, a method for driving any of them, and a method for manufacturing any of them.

Note that in this specification and the like, a semiconductor device generally means a device that can function by utilizing semiconductor characteristics. A transistor, a semiconductor circuit, an arithmetic device, a memory device, and the like are each an embodiment of the semiconductor device. In addition, an imaging device, an electro-optical device, a power generation device (e.g., a thin film solar cell and an organic thin film solar cell), and an electronic device each may include a semiconductor device.

2. Description of the Related Art

Display devices using organic electroluminescent (EL) elements or liquid crystal elements have been known. Examples of the display device also include a light-emitting device provided with a light-emitting element such as a light-emitting diode (LED), and electronic paper performing display with an electrophoretic method or the like.

The organic EL element generally has a structure in which a layer containing a light-emitting organic compound is provided between a pair of electrodes. When voltage is applied to this element, light emission can be obtained from the light-emitting organic compound. With use of such an organic EL element, thin, lightweight, high-contrast, and low-power-consumption display devices can be achieved.

Patent Document 1 discloses a flexible light-emitting device using an organic EL element.

### REFERENCE

### Patent Document

[Patent Document 1] Japanese Published Patent Application No. 2014-197522

### SUMMARY OF THE INVENTION

It is known that an organic EL element deteriorates in an environment containing impurities such as water. To prevent entry of impurities, a barrier layer including a material in which impurities hardly diffuse (a material having a barrier property) is preferably provided.

A flexible device, typified by a flexible display, can be obtained by providing a semiconductor element such as a transistor and a display element such as an organic EL element over a flexible substrate (film). It is difficult to enhance the moisture resistance of the flexible substrate, and therefore, the above-described barrier layer is essential.

However, in some cases, a material having a high barrier property is cracked by the stress applied to the material by deformation such as bending of the flexible device, which significantly impairs the barrier property of the material.

An object of one embodiment of the present invention is to provide a display device having high reliability. Another object is to provide a flexible device having high reliability, particularly a flexible display having high reliability. Another object is to provide a flexible device capable of being bent repeatedly, particularly a flexible display capable of being bent repeatedly.

An object of one embodiment of the present invention is to provide a display device, an electronic device, or the like that has a novel structure.

Note that the descriptions of these objects do not disturb the existence of other objects. In one embodiment of the present invention, there is no need to achieve all of these objects. Objects other than the above objects can be derived from the description of the specification and like.

One embodiment of the present invention is a display device including a first substrate, a second substrate, a display element, a light-blocking layer, a first barrier layer, and an adhesive layer. The first substrate and the second substrate are positioned to face each other. The display element, the light-blocking layer, the first barrier layer, and the adhesive layer are between the first substrate and the second substrate. The display element is between the first substrate and the adhesive layer. The light-blocking layer is between the second substrate and the adhesive layer. The first barrier layer includes a region between the light-blocking layer and the adhesive layer.

Another embodiment of the present invention is a display device including a first substrate, a second substrate, a display element, a light-blocking layer, a coloring layer, a barrier layer, and an adhesive layer. The first substrate and the second substrate are positioned to face each other. The display element, the light-blocking layer, the barrier layer, the coloring layer, and the adhesive layer are between the first substrate and the second substrate. The display element is between the first substrate and the adhesive layer. The light-blocking layer and the coloring layer are between the second substrate and the adhesive layer. The barrier layer includes a region between the light-blocking layer and the coloring layer.

It is preferable that the light-blocking layer be between the barrier layer and the second substrate and the coloring layer be between the barrier layer and the adhesive layer.

It is preferable that the first barrier layer include a material having a higher Young's modulus than at least one of the light-blocking layer and the adhesive layer.

It is preferable that each of the first substrate and the second substrate have flexibility and include a material having a lower Young's modulus than the material included in the first barrier layer.

In the above structure, it is preferable to include a second barrier layer. It is preferable that the second barrier layer include a region between the first substrate and the display element. It is preferable that the second barrier layer include a material having a higher Young's modulus than the light-blocking layer.

It is preferable that the first barrier layer include at least one of a silicon oxide, a silicon oxynitride, a silicon nitride oxide, a silicon nitride, an aluminum oxide, and an aluminum nitride. It is preferable that two or more insulating films be stacked in the first barrier layer.

In the above structure, it is preferable to include a transistor. It is preferable that the transistor be between the first substrate and the adhesive layer.

In the above structure, it is preferable to include a conductive layer. It is preferable that the conductive layer be between the barrier layer and the second substrate. It is preferable that the conductive layer have an island-like top surface shape.

It is preferable that the conductive layer include a metal oxide, or it is preferable that the conductive layer include a metal or an alloy and have a mesh-like top surface shape.

It is preferable that the conductive layer include a region between the light-blocking layer and the barrier layer and a region overlapping with the light-blocking layer.

One embodiment of the present invention can provide a display device having high reliability, a flexible device having high reliability, or a flexible display having high reliability. One embodiment of the present invention can provide a flexible device capable of being bent repeatedly, particularly a flexible display capable of being bent repeatedly.

One embodiment of the present invention can provide a display device, an electronic device, or the like that has a novel structure.

### BRIEF DESCRIPTION OF THE DRAWINGS

FIG. 1 is a cross-sectional view illustrating a display device.

FIGS. 2A and 2B are cross-sectional views each illustrating a display device.

FIGS. 3A to 3C are cross-sectional views each illustrating a display device.

FIGS. 4A and 4B are cross-sectional views each illustrating a display device.

FIG. 5 is a cross-sectional view illustrating a display device.

FIGS. 6A and 6B are cross-sectional views each illustrating a display device.

FIGS. 7A and 7B are cross-sectional views each illustrating a display device.

FIGS. 8A to 8D illustrate a manufacturing method for a display device.

FIGS. 9A to 9E illustrate the manufacturing method for the display device.

FIGS. 10A and 10B illustrate the manufacturing method for the display device.

FIGS. 11A and 11B illustrate the manufacturing method for the display device.

FIGS. 12A to 12D illustrate a manufacturing method for a display device.

FIG. 13 is a perspective view illustrating a display device.

FIG. 14 is a cross-sectional view illustrating a display device.

FIG. 15 is a cross-sectional view illustrating a display device.

FIGS. 16A to 16D illustrate input devices.

FIGS. 17A to 17D illustrate input devices.

FIGS. 18A and 18B are perspective views illustrating a display device.

FIG. 19 is a cross-sectional view illustrating the display device.

FIGS. 20A and 20B are perspective views illustrating a display device.

FIG. 21 is a cross-sectional view illustrating the display device.

FIGS. 22A and 22B are diagrams illustrating a method for driving an input device.

FIGS. 23A to 23D are cross-sectional views illustrating a method for forming an EL layer.

FIG. 24 is a conceptual diagram illustrating a droplet discharge apparatus.

FIGS. 25A to 25F illustrate electronic devices and a lighting device.

FIGS. 26A to 26I illustrate electronic devices.

FIGS. 27A to 27F illustrate electronic devices.

### DETAILED DESCRIPTION OF THE INVENTION

Embodiments will be described in detail with reference to the drawings. Note that the present invention is not limited to the following description, and it will be easily understood by those skilled in the art that various changes and modifications can be made without departing from the spirit and scope of the present invention. Therefore, the present invention should not be construed as being limited to the description in the following embodiments.

Note that in the structures of the invention described below, the same portions or portions having similar functions are denoted by the same reference numerals in different drawings, and description of such portions is not repeated. Furthermore, the same hatch pattern is used for portions having similar functions, and the portions are not especially denoted by reference numerals in some cases.

Note that in each drawing described in this specification, the size, the layer thickness, or the region of each component is exaggerated for clarity in some cases. Therefore, embodiments of the present invention are not limited to such a scale.

Note that ordinal numbers such as “first” and “second” in this specification and the like are used in order to avoid confusion among components, and the terms do not limit the components numerically.

A transistor is a kind of semiconductor elements and can achieve amplification of current or voltage, switching operation for controlling conduction or non-conduction, or the like. A transistor in this specification includes, in its category, an insulated-gate field-effect transistor (IGFET) and a thin film transistor (TFT).

### Embodiment 1

This embodiment describes structure examples and a manufacturing method example of a display device (a display panel) that is given as an example of a flexible device of one embodiment of the present invention.

One embodiment of the present invention includes a plurality of display elements, a light-blocking layer, an adhesive layer, and a barrier layer between a pair of substrates. The pair of substrates is also referred to as first substrate and second substrate in some cases. The display elements are between the first substrate and the adhesive layer. The light-blocking layer is between the second substrate and the adhesive layer.

Typical examples of the display element include a light-emitting element such as an organic EL element (organic light-emitting diode (OLED)) or a quantum-dot light-emitting diode (QLED). Furthermore, a light-emitting diode (LED) may be used.

Other examples of the display element include a liquid crystal element, a micro electro mechanical systems (MEMS) element, an electron emitter, and another optical element. Examples of MEMS display elements include a MEMS shutter display element and an optical interference type MEMS display element. A carbon nanotube may be used for the electron emitter. Examples of another optical element include an element using a microcapsule method, an electrophoretic method, an electrowetting method, an Electronic Liquid Powder (registered trademark) method, or the like.

The adhesive layer is provided between the first substrate and the second substrate, and the display device has a structure in which the display element is encapsulated by the first substrate, the second substrate, and the adhesive layer. The light-blocking layer is between two display elements that are adjacent in plan view, and the light-blocking layer has a function of preventing color mixing of light emitted from these two display elements.

The barrier layer is preferably provided between the adhesive layer and the light-blocking layer, whereby the barrier layer can be placed in a position close to the neutral plane of the display device. Thus, stress that is applied to the barrier layer by deformation such as bending of the display device can be reduced even in the case where the barrier layer is formed using a material that is easily cracked. Consequently, the barrier layer can be prevented from being cracked.

The display device may have a structure including a coloring layer. In this structure, the barrier layer is between the adhesive layer and one of the light-blocking layer and the coloring layer. In this case, the barrier layer may be between the light-blocking layer and the coloring layer or between the adhesive layer and both the coloring layer and the light-blocking layer.

The barrier layer can be formed using a material that is highly resistant to moisture. An inorganic insulating material can be suitably used, for example. As a material that can be used for the barrier layer, an oxide or a nitride of a semiconductor material such as silicon, an oxide or a nitride of a metal such as aluminum, or the like can be used, for example. An inorganic insulating material such as a silicon nitride film, a silicon oxynitride film, a silicon oxide film, a silicon nitride oxide film, an aluminum oxide film, or an aluminum nitride film can be suitable used. The barrier layer preferably has a stacked-layer structure including the above-described insulating film, in which case the resistance to moisture can be increased. It is particularly preferable to have a stacked-layer structure of two or more of the above-described insulating films.

Note that in this specification, a nitride oxide is a substance which includes more nitrogen than oxygen, and an oxynitride is a substance which includes more oxygen than nitrogen. The element content can be measured by, for example, Rutherford back scattering spectrometry (RBS).

The moisture-resistance property of the barrier layer depends on not only a material thereof but also a density and a thickness thereof, film formation conditions thereof, and the like in some cases. Therefore, the barrier layer is preferably formed under conditions that achieve a sufficiently small permeation amount of water vapor. For example, as the insulating film highly resistant to moisture, it is possible to use a film of which the permeation amount of water vapor is lower than or equal to 1×10⁻⁵ [g/(m²·day)], preferably lower than or equal to 1×10⁻⁶ [g/(m²·day)], further preferably lower than or equal to 1×10⁻⁷ [g/(m²·day)], still further preferably lower than or equal to 1×10⁻⁸ [g/(m²·day)].

In such a barrier layer, moisture resistance is increased but elasticity is decreased, and therefore, the barrier layer is broken in some cases by being subjected to high stress. The barrier layer is likely to be broken particularly in the case where the Young's modulus of the barrier layer is higher than that of a flexible substrate, the light-blocking layer, the coloring layer, the adhesive layer, or the like at temperatures in a use environment. This is because the barrier layer is likely to have the greatest stress concentration when the display device is subjected to deformation such as bending. Furthermore, a layer that is farther from the neutral plane receives the higher stress when the display device is subjected to deformation such as bending.

Thus, by providing the barrier layer at least between the adhesive layer and one or both of the light-blocking layer and the coloring layer as described above, the barrier layer can be close to the neutral plane. This can prevent the barrier layer from being cracked. Thus, a display device having extremely high reliability can be obtained.

Furthermore, by providing the barrier layer having a high Young's modulus, i.e., the barrier layer that hardly deforms elastically, in a position close to the neutral plane, a synergistic effect is produced. That is, a force for bending the display device is reduced, and the display device can be bent with a smaller force.

For example, the barrier layer is preferably positioned such that the distance between the neutral plane of the display device and a top surface, a bottom surface, or a neutral plane of the barrier layer is 30% or less, preferably 20% or less, more preferably 10% or less of the total thickness of the display device. Note that the total thickness of the display device is a distance between two outer surfaces of the pair of substrates in the direction of a normal. Furthermore, the neutral plane of the display device corresponds to a plane passing through the middle of the thickness of the display device, and the neutral plane of the barrier layer corresponds to a plane passing through the middle of the thickness of the barrier layer.

Here, another barrier layer (also referred to as a second barrier layer) is preferably provided between the display element and the first substrate. The structure in which the display element is sandwiched between the two barrier layers can further increase reliability. The second barrier layer can have a structure similar to that of the first barrier layer.

A transistor that is electrically connected to the display element may be provided. The transistor can be formed between the adhesive layer and the first substrate, for example. In the case of providing the transistor, the second barrier layer is preferably positioned between the transistor and the first substrate. This can prevent diffusion of impurities into the transistor and change in the electrical characteristics of the transistor.

Here, a conductive layer may be provided between the barrier layer and the second substrate. The conductive layer is a conductive layer serving as an electrode of a touch sensor, a conductive layer for shielding an electric field, or the like.

The conductive layer can be formed using a conductive material such as a metal, an alloy, or a metal oxide. In the case where the conductive layer has a higher Young's modulus than the flexible substrate, the light-blocking layer, the coloring layer, the adhesive layer, or the like at temperatures in a use environment, the conductive layer might be cracked by deformation such as bending of the display device. In view of this, the conductive layer that is provided between the barrier layer and the second substrate is preferably processed into an island-like top surface shape. Thus, stress that is applied to the conductive layer can be relieved, whereby the conductive layer can be prevented from being damaged. Moreover, because the conductive layer is processed into an island-like shape, a force for bending the display device can be reduced.

In particular, the conductive layer that is provided between the barrier layer and the second substrate preferably has a plurality of periodic openings, particularly a mesh or lattice shape. In the case where the conductive layer has such a shape, stress that is applied to the conductive layer can be relieved more effectively. In the case where the conductive layer is processed into an island-like shape and has a plurality of openings (including a mesh or lattice shape), stress that is applied to the conductive layer can be relieved more effectively even when the conductive layer is apart from the neutral plane.

A metal and an alloy have higher ductility and higher malleability than an inorganic insulating material. Therefore, in the case where the conductive layer is formed using a metal or an alloy, the conductive layer is hardly ruptured even when stress is applied to the conductive layer by deformation such as bending of the display device. Therefore, such a conductive layer may have a Young's modulus substantially the same as or higher than the barrier layer. The conductive layer that is provided between the barrier layer and the second substrate can be formed using a material having a wider elastic range than the barrier layer, i.e., a material having a higher yield point in a stress-strain curve than the barrier layer, or a material to be ruptured with stress higher than stress to rupture the barrier layer.

Specific structure examples and a manufacturing method of a display device are described below with reference to drawings.

### Structure Examples

### Cross-Sectional Structure Example 1

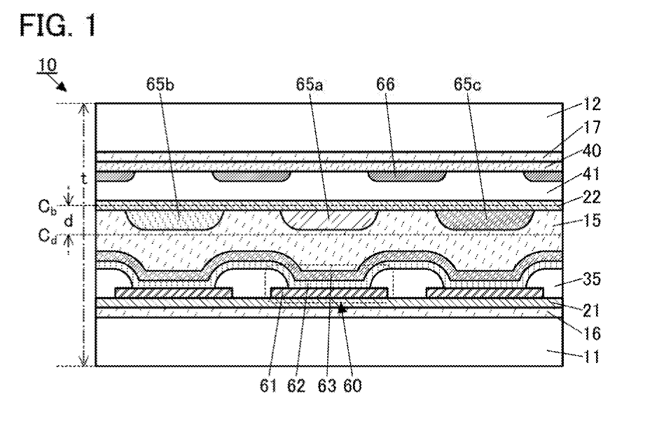

FIG. 1 is a schematic cross-sectional view of a pixel portion (also referred to as a display portion, a display region, or the like) of a display device 10 of one embodiment of the present invention.

The display device 10 includes a substrate 11, a substrate 12, a display element 60, a coloring layer 65a, a coloring layer 65b, a coloring layer 65c, a light-blocking layer 66, a barrier layer 21, a barrier layer 22, and the like. In FIG. 1, an example in which an organic EL element is used as the display element 60 is shown.

The substrate 11 and the barrier layer 21 are bonded to each other using an adhesive layer 16. The display element 60 is provided over the barrier layer 21. The display element 60 has a structure in which a conductive layer 61, an EL layer 62, and a conductive layer 63 are stacked in this order from the barrier layer 21 side.

In this structure, an insulating layer 35 is provided to cover an end portion of the conductive layer 61, and the EL layer 62 and the conductive layer 63 are stacked to cover a top surface of the insulating layer 35 and an exposed top surface of the conductive layer 61. The display element 60 emits white light. Of light emitted from the display element 60 toward the substrate 12, light other than that in a predetermined wavelength range is absorbed by the coloring layer 65a, the coloring layer 65b, or the coloring layer 65c and is emitted outward through the substrate 12. For example, three kinds of coloring layer, i.e., a red (R) coloring layer, a green (G) coloring layer, and a blue (B) coloring layer are used as the coloring layer 65a, the coloring layer 65b, and the coloring layer 65c, whereby the display device 10 can perform full-color display.

A surface of the substrate 12 on the substrate 11 side and an insulating layer 40 are bonded to each other using an adhesive layer 17. The light-blocking layer 66 is provided on the substrate 11 side of the insulating layer 40, and an insulating layer 41 is provided to cover the light-blocking layer 66. The barrier layer 22 is provided on the substrate 11 side of the insulating layer 41, and the coloring layer 65a, the coloring layer 65b, and the coloring layer 65c are provided on the substrate 11 side of the barrier layer 22.

The light-blocking layer 66 includes a region overlapping with a portion between two adjacent display elements 60. The coloring layer 65a, the coloring layer 65b, and the coloring layer 65c each include a region overlapping with one display element 60.

An adhesive layer 15 has a function of bonding the substrate 11 and the substrate 12 to each other. Specifically, the adhesive layer 15 is positioned between the conductive layer 63 and exposed surfaces of the coloring layer 65a, the coloring layer 65b, the coloring layer 65c, and the barrier layer 22 in FIG. 1.

The barrier layer 21 and the barrier layer 22 can be formed using a material highly resistant to moisture. Because the display element 60 is sandwiched between the barrier layer 21 and the barrier layer 22, the display device 10 has extremely high reliability.

The substrate 11 and the substrate 12 can be formed using a flexible material. This achieves a bendable display device.

The barrier layer 22 is preferably formed using an inorganic insulating material highly resistant to moisture. As such an inorganic insulating material, it is possible to use a material that has a higher Young's modulus in the use environment of the display device 10 than at least any of the light-blocking layer 66, the adhesive layer 17, and the coloring layers 65a to 65c. It is preferable to use, as the barrier layer 22, a material having a high Young's modulus in the use environment of the display device 10 in the case where a flexible material is used as the substrate 12. In particular, it is preferable that the difference in Young's modulus be 10 times or more, more preferably 20 times or more, still more preferably 50 times or more, still further preferably 100 times or more. Note that the use environment of the display device 10 refers to, for example, a temperature range of −20 ° C. to 60° C. inclusive, −10 ° C. to 50° C. inclusive, or 0° C. to 40° C. inclusive.

Another preferred material for the barrier layer 22 is a material whose Young's modulus in the use environment of the display device 10 is 10 times or more, preferably 20 times or more, more preferably 50 times or more, still more preferably 100 times or more as high as a Young's modulus of one or more of the insulating layer 40, the insulating layer 41, the adhesive layer 15, the insulating layer 35, the adhesive layer 16, and the substrate 12.

For example, the Young's modulus of the barrier layer 22 is preferably greater than or equal to 10 GPa and less than or equal to 1000 GPa, more preferably greater than or equal to 20 GPa and less than or equal to 900 GPa, still more preferably greater than or equal to 20 GPa and less than or equal to 800 GPa. Note that in measurement of Young's modulus, standards such as ISO527, JISK7161, JISK7162, JISK7127, ASTMD638, and ASTMD882 can be referred to.

In FIG. 1, a total thickness t of the display device 10, a neutral plane C_{d} of the display device 10, a neutral plane C_{b} of the barrier layer 22, and a distance d between the neutral plane C_{d} and the neutral plane C_{b} are shown. Here, it is preferable to include a region where a value obtained by dividing the distance d by the total thickness t is 0 or more and 0.3 or less, preferably 0.2 or less, more preferably 0.1 or less. When the barrier layer 22 is closer to the neutral plane Ca of the display device 10, stress that is applied to the barrier layer 22 by deformation such as bending of the display device 10 can be further reduced.

The total thickness t of the display device 10 is preferably 1 μm or more and 1 mm or less, or 5 μm or more and 500 μm or less, preferably 10 μm or more and 300 μm or less, more preferably 15 μm or more and 200 μm or less, still more preferably 20 μm or more and 100 μm or less. In the display device 10 with a smaller thickness, the distance between the barrier layer 22 and the neutral plane of the display device 10 can be smaller and stress that is applied to the barrier layer 22 can be further reduced.

In the example shown in FIG. 1, the insulating layer 41 is provided to cover the light-blocking layer 66, and the barrier layer 22 is provided on the substrate 11 side of the insulating layer 41. The insulating layer 41 serves as a planarization layer. In the case where the barrier layer 22 is formed over a very rough surface, for example, the formed barrier layer 22 might have a locally low-density and brittle portion, a pinhole, or the like. By providing the insulating layer 41 serving as a planarization layer, the barrier layer 22 can be formed over a flat surface and be highly resistant to water.

In the example shown in FIG. 1, the coloring layer 65a, the coloring layer 65b, and the coloring layer 65c are provided in positions closer to the substrate 11 than the barrier layer 22. Thus, the distance between the display element 60 and each coloring layer can be reduced, so that viewing angle characteristics can be improved. Furthermore, light from the display element 60 including light emitted obliquely can be taken out effectively, reducing power consumption. Moreover, a display device with a small thickness can be achieved.

The above is the description of Cross-sectional structure example 1.

### Cross-Sectional Structure Example 2

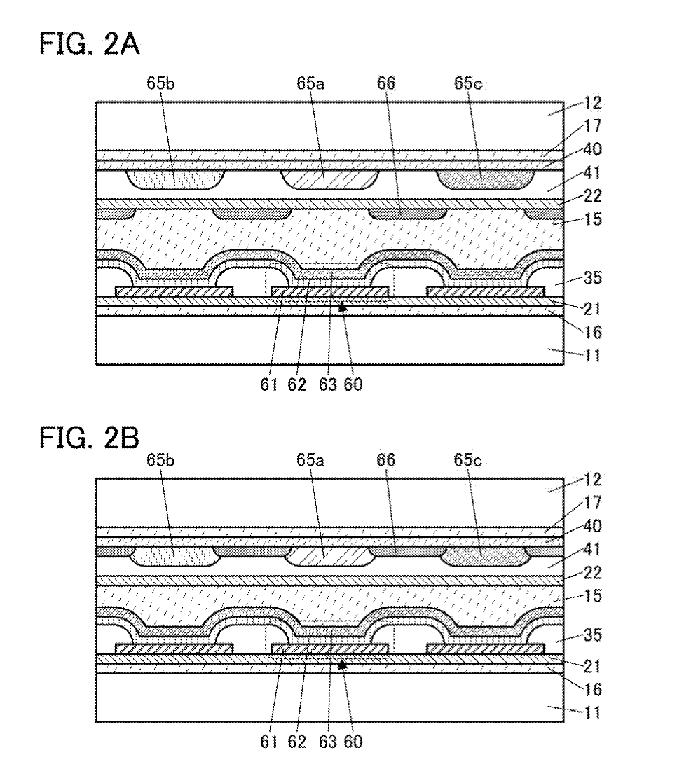

FIG. 2A is a schematic cross-sectional view of the case where the barrier layer 22 is positioned between the light-blocking layer 66 and the coloring layers 65a to 65c.

In FIG. 2A, the coloring layer 65a, the coloring layer 65b, and the coloring layer 65c are provided on the substrate 11 side of the insulating layer 40, and the insulating layer 41, the barrier layer 22, and the light-blocking layer 66 are stacked to cover these layers.

In this case, the barrier layer 22 is preferably formed using a material with a higher Young's modulus than at least one or more of the coloring layers 65a to 65c, the insulating layer 40, the insulating layer 41, the adhesive layer 17, and the substrate 12.

### Cross-Sectional Structure Example 3

FIG. 2B shows an example of the case where the light-blocking layer 66, the coloring layer 65a, the coloring layer 65b, and the coloring layer 65c are positioned between the barrier layer 22 and the substrate 12.

In FIG. 2B, the light-blocking layer 66, the coloring layer 65a, the coloring layer 65b, and the coloring layer 65c are provided on the substrate 11 side of the insulating layer 40, and furthermore, the insulating layer 41 and the barrier layer 22 are stacked to cover these layers.

Such a structure is preferable because the barrier layer 22 can be provided in a position closer to the neutral plane of the display device 10.

In this case, the barrier layer 22 is preferably formed using a material with a higher Young's modulus than at least one or more of the coloring layers 65a to 65c, the light-blocking layer 66, the insulating layer 40, the insulating layer 41, the adhesive layer 17, and the substrate 12.

### Modification Example 1

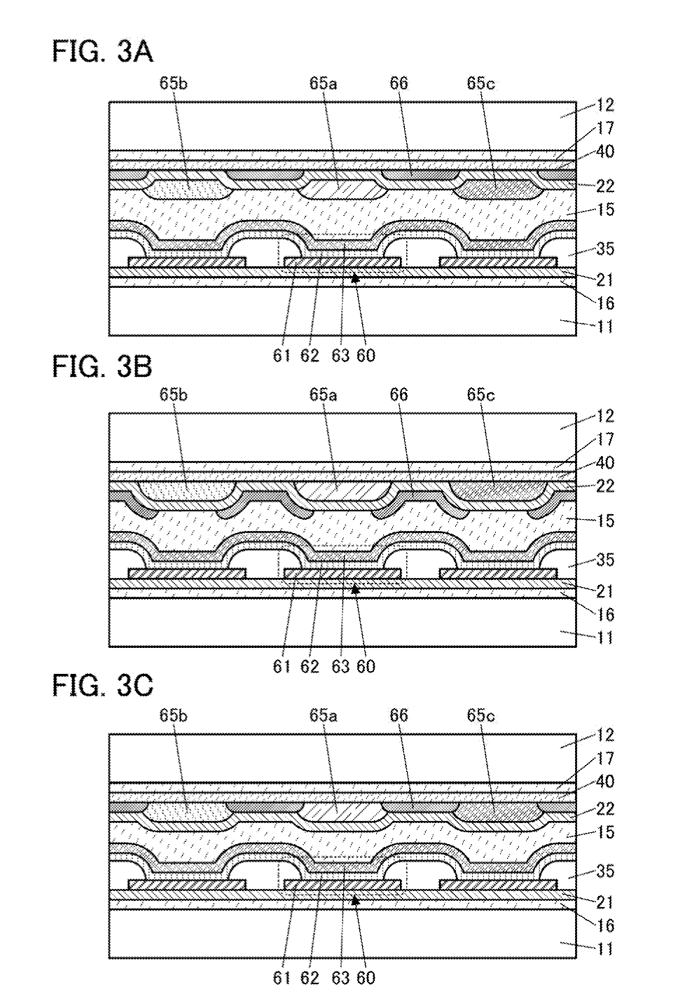

FIG. 3A shows an example of the case where the insulating layer 41 in FIG. 1 is not provided. FIG. 3B shows an example of the case where the insulating layer 41 in FIG. 2A is not provided. FIG. 3C shows an example of the case where the insulating layer 41 in FIG. 2B is not provided.

The display device 10 having such a structure can have a small thickness, so that stress that is applied to the barrier layer 22 by deformation such as bending of the display device 10 can be reduced. Furthermore, a step of forming the insulating layer 41 can be omitted.

### Modification Example 2

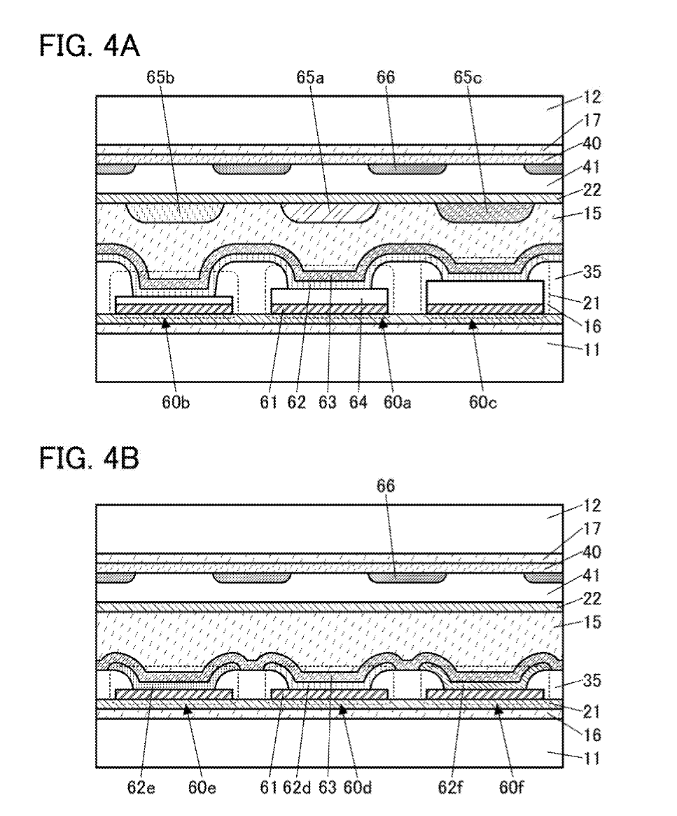

FIG. 4A shows an example of the case where display elements have different structures. In the display element shown in FIG. 4A, an optical adjustment layer 64 is provided between the conductive layer 61 and the EL layer 62.

The optical adjustment layer 64 can be formed using a conductive material that transmits visible light. In this case, it is preferable that the conductive layer 61 be formed using a material having a property of reflecting visible light and that the conductive layer 63 be formed using a material having a property of transmitting and reflecting visible light (also referred to as a semi-transmissive semi-reflective material). With such a structure, each of the display elements can have a microcavity structure, so that the color purity of light emitted from each of the display elements can be increased. Furthermore, with the use of the coloring layers, the color purity of light extracted through the substrate 12 can be increased. Consequently, the display device can have high color reproducibility.

In FIG. 4A, optical adjustment layers 64 of a display element 60a, a display element 60b, and a display element 60c have different thicknesses. Although the optical adjustment layer 64 is provided in each of the display elements 60a to 60c in the structure shown in the figure, the optical adjustment layer 64 is not necessarily provided in the display element that emits light with the shortest wavelength (e.g., blue light).

Note that in Modification example 2, a structure between the adhesive layer 15 and the substrate 12 can be formed by combining the structures described in Cross-sectional structure examples 1 to 3, Modification example 1, and the like as appropriate.

### Modification Example 3

FIG. 4B shows an example of the case where structures of display elements are different from those described above. In the example shown here, different EL layers are formed in display elements of different colors.

In the example shown in FIG. 4B, a display element 60d including an EL layer 62d, a display element 60e including an EL layer 62e, and a display element 60f including an EL layer 62f are provided. The EL layer 62d, the EL layer 62e, and the EL layer 62f include light-emitting layers emitting different colors.

Note that although each of the EL layers is completely divided between the display elements in the example shown in FIG. 4B, a part of a layer forming the EL layer may extend between the display elements to be shared by the display elements.

Note that in the example shown in FIG. 4B, the coloring layer is not provided because the display elements exhibit different colors, but the coloring layer may be provided as in Cross-sectional structure examples 1 to 3 and the like.

In this case, the barrier layer 22 is preferably formed using a material with a higher Young's modulus than at least one or more of the light-blocking layer 66, the insulating layer 40, the insulating layer 41, the adhesive layer 17, and the substrate 12.

Note that a structure between the adhesive layer 15 and the substrate 12 in Modification example 3 can be formed by combining the structures described in Cross-sectional structure examples 1 to 3, Modification example 1, and the like as appropriate.

### Cross-Sectional Structure Example 4

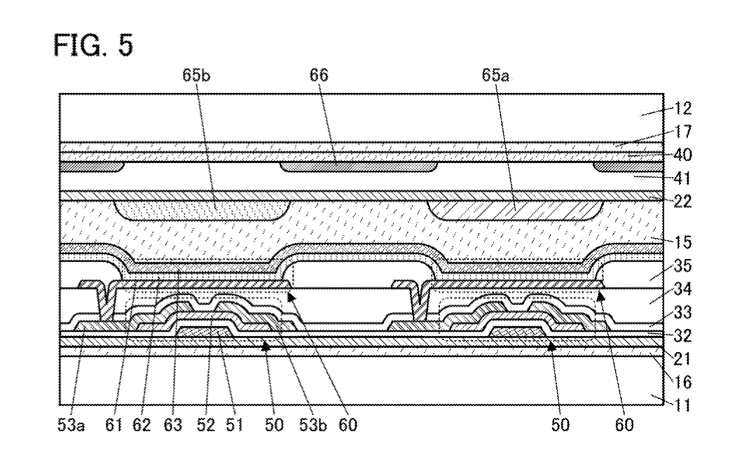

FIG. 5 shows a cross-sectional structure example of the case of including a transistor 50 electrically connected to the display element 60. In the figure, a bottom-gate transistor is shown as an example of the transistor 50.

In FIG. 5, an insulating layer 32, an insulating layer 33, an insulating layer 34, the transistor 50, and the like are provided in addition to the structure shown in FIG. 1.

The transistor 50 includes a conductive layer 51 partly serving as a gate, the insulating layer 32 partly serving as a gate insulating layer, a semiconductor layer 52, a conductive layer 53a partly serving as one of a source and a drain, and a conductive layer 53b partly serving as the other of the source and the drain.

The insulating layer 33 is provided to cover the transistor 50, and the insulating layer 34 is provided over the insulating layer 33. The insulating layer 33 has a function of preventing impurities from diffusing into the transistor 50. The insulating layer 34 serves as a planarization layer. Note that the insulating layer 34 is not necessarily provided when not needed. In the case where the insulating layer 34 is formed using a material in which impurities do not diffuse easily, the insulating layer 33 may be omitted.

The conductive layer 61 is provided over the insulating layer 34 and is electrically connected to the conductive layer 53a through openings provided in the insulating layer 34 and the insulating layer 33.

In FIG. 5, the display element 60 and the transistor 50 are sandwiched between the barrier layer 21 and the barrier layer 22. Thus, a variation in the electrical characteristics of the transistor 50 can be reduced, so that the display device 10 can have high reliability.

In this case, the barrier layer 22 is preferably formed using a material with a higher Young's modulus than at least one or more of the light-blocking layer 66, the insulating layer 40, the insulating layer 41, the adhesive layer 17, and the substrate 12.

In FIG. 5, a structure over the adhesive layer 15, a structure of the display element 60, and the like are similar to those shown in Cross-sectional structure example 1. Note that without limitation thereon, the structures described in other Cross-sectional structure examples and Modification examples can be used in combination as appropriate.

### Cross-Sectional Structure Example 5

A structure in which a conductive layer is provided between the barrier layer 22 and the substrate 12 is described below. In particular, a structure in which a conductive layer serves as an electrode of a touch sensor is described in this example. A structure in which a touch sensor function is added to a display device (a display panel) can also be referred to as a touch panel.

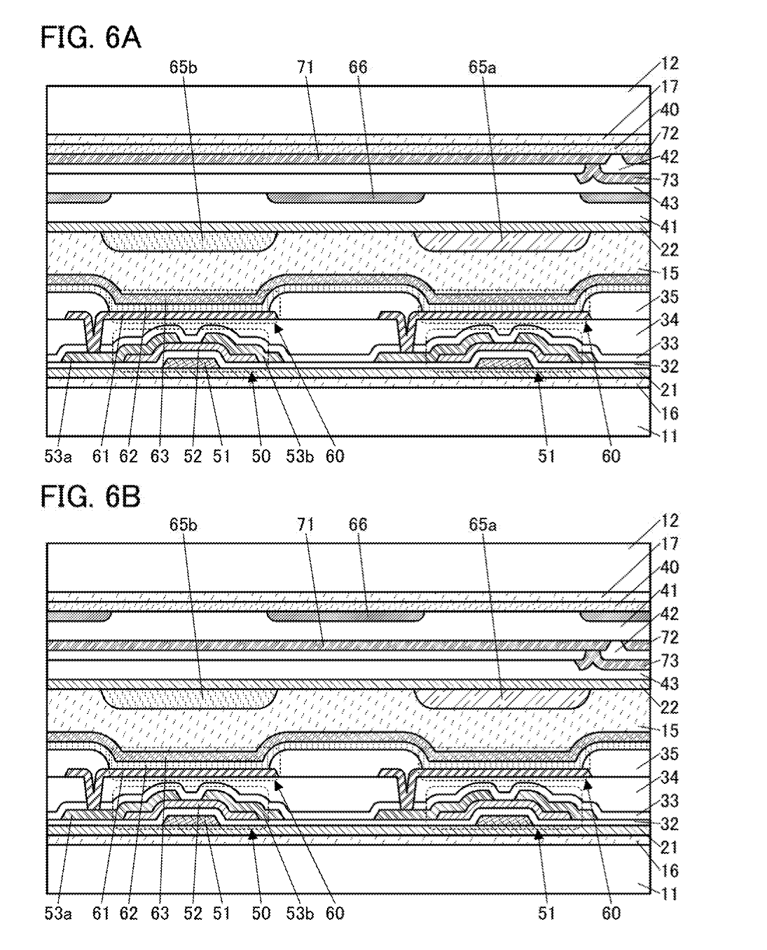

FIG. 6A is a schematic cross-sectional view of a display device described below as an example. In FIG. 6A, a conductive layer 71, a conductive layer 72, a conductive layer 73, an insulating layer 42, and an insulating layer 43 are provided in addition to the structure shown in FIG. 5.

In FIG. 6A, the conductive layer 71 and the conductive layer 72 are provided on the substrate 11 side of the insulating layer 40. The insulating layer 42 is provided to cover the conductive layer 71 and the conductive layer 72, and the conductive layer 73 is provided on the substrate 11 side of the insulating layer 42. The conductive layer 73 is electrically connected to the conductive layer 71 through an opening provided in the insulating layer 42.

The insulating layer 43 is provided to cover an exposed surface of the insulating layer 42 and the conductive layer 73. In addition, the light-blocking layer 66, the insulating layer 41, the barrier layer 22, the coloring layer 65a, the coloring layer 65b, and the like are provided on the substrate 11 side of the insulating layer 43.

The conductive layer 71 and the conductive layer 72 each serve as one of a pair of conductive layers forming a touch sensor. The conductive layer 71 and the conductive layer 72 are provided to extend in directions intersecting with each other. In the example shown in FIG. 6A, the conductive layer 71 extends in a lateral direction, and the conductive layer 72 extends in a depth direction.

In the example, the conductive layer 71 and the conductive layer 72 are formed on the same surface. In order to prevent the electrical short-circuit between the conductive layer 71 and the conductive layer 72 at the intersection thereof, two conductive layers 71 (one of which is not shown) that are positioned with the conductive layer 72 therebetween are electrically connected to each other by the conductive layer 73 (in other words, a bridge is formed). Note that in the case where an insulating layer is provided between the conductive layer 71 and the conductive layer 72 and the conductive layer 71 and the conductive layer 72 are formed over different surfaces, the conductive layer 73 may be omitted.

The conductive layer 71 and the conductive layer 72 include a conductive material having a light-transmitting property. Thus, light emitted from the display element 60 can be taken out through the conductive layer 71 or the conductive layer 72. The conductive layer 73 may have a light-transmitting property and may include a conductive material that does not have a light-transmitting property. For example, by using a material including a metal or an alloy as the conductive layer 73, the electrical resistance can be reduced as compared with the case of using a material having a light-transmitting property.

In the example shown in FIG. 6B, the light-blocking layer 66 and the insulating layer 41 are provided in positions closer to the substrate 12 than the conductive layer 71 and the like. By using such a structure, the conductive layer 71, the conductive layer 72, and the conductive layer 73 can be close to the neutral plane of the display device 10. Thus, stress that is applied by deformation such as bending of the display device 10 can be relieved even in the case where the conductive layer 71, the conductive layer 72, and the conductive layer 73 are formed using a material with a high Young's modulus.

In this example, the barrier layer 22 is preferably formed using a material with a higher Young's modulus than at least one or more of the light-blocking layer 66, the insulating layer 40, the insulating layer 41, the insulating layer 42, the insulating layer 43, the adhesive layer 17, and the substrate 12.

In FIGS. 6A and 6B, the positional relation between the coloring layer 65a, the coloring layer 65b, and the barrier layer 22, the structure of the display element 60, and the like are similar to those in Cross-sectional structure example 1. Note that without limitation thereon, the structures shown in other Cross-sectional structure examples and Modification examples can be used in combination as appropriate.

### Cross-Sectional Structure Example 6

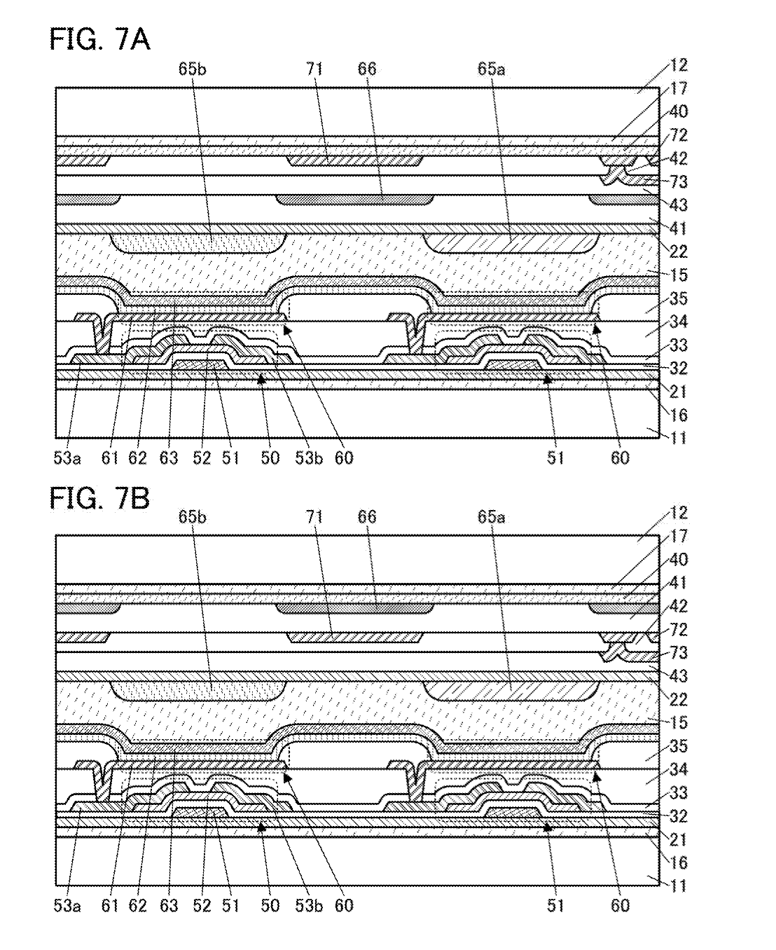

FIG. 7A shows an example of the case where structures of the conductive layer 71 and the conductive layer 72 are different from those shown in FIG. 6A.

In the example shown in FIG. 7A, the conductive layer 71 includes an opening. The conductive layer 71 is provided in a position overlapping with the light-blocking layer 66. The opening of the conductive layer 71 is provided to overlap with the display element 60 or the coloring layer 65a (and the coloring layer 65b). The same applies to the conductive layer 72. The conductive layer 73 is preferably provided in a position overlapping with the light-blocking layer 66 and may have an opening like the conductive layer 71.

In such a structure, light emitted from the display element 60 does not pass through the conductive layer 71 and the like, so that the light extraction efficiency can be increased and the power consumption can be reduced. Furthermore, light absorption by the conductive layer 71 and the like does not occur, so that the color purity of light emitted from the display device 10 can be increased.

In FIG. 7A, the conductive layer 71, the conductive layer 72, and the conductive layer 73 can be formed using a conductive material that blocks visible light. For example, a conductive material including a metal or an alloy can be used. In this case, the electrical resistances of the conductive layer 71, the conductive layer 72, and the conductive layer 73 can be significantly reduced as compared with the case of using a material having a light-transmitting property. Thus, the conductive layer 71 and the like can have a small thickness, and various advantageous effects are obtained such as a reduction in the stress that is applied to the conductive layer 71 and the like and a reduction in the thickness of the display device 10. Furthermore, the conductivity of the conductive layer 71 and the like is increased, so that the area of a display region can be enlarged.

In the example shown in FIG. 7B, the light-blocking layer 66 and the insulating layer 41 are provided in a position closer to the substrate 12 side than the conductive layer 71 and the like. In such a structure, the conductive layer 71, the conductive layer 72, and the conductive layer 73 can be close to the neutral plane of the display device 10. Thus, stress that is applied by deformation such as bending of the display device 10 can be relieved even in the case where the conductive layer 71, the conductive layer 72, and the conductive layer 73 are formed using a material with a high Young's modulus.

Furthermore, because the light-blocking layer 66 is provided closer to the substrate 12 side than the conductive layer 71 and the like and covers the conductive layer 71 and the like, external light does not reach the conductive layer 71 and the like, and reflection of external light by the conductive layer 71 and the like can be prevented. Thus, the visibility of the display device can be increased.

In the example, the barrier layer 22 is preferably formed using a material with a higher Young's modulus than at least one or more of the light-blocking layer 66, the insulating layer 40, the insulating layer 41, the insulating layer 42, the insulating layer 43, the adhesive layer 17, and the substrate 12.

In FIGS. 7A and 7B, the positional relation between the coloring layer 65a, the coloring layer 65b, and the barrier layer 22, the structure of the display element 60, and the like are similar to those in Cross-sectional structure example 1. Note that without limitation thereon, the structures shown in other Cross-sectional structure examples and Modification examples can be used in combination as appropriate.

### Manufacturing Method Example

An example of a method for manufacturing a display device will be described below with reference to drawings. Here, description is made using the display device 10 shown in FIG. 5 as an example.

Note that thin films included in the display device (i.e., the insulating film, the semiconductor film, the conductive film, and the like) can be formed by any of a sputtering method, a chemical vapor deposition (CVD) method, a vacuum evaporation method, a pulsed laser deposition (PLD) method, an atomic layer deposition (ALD) method, and the like. As the CVD method, a plasma-enhanced chemical vapor deposition (PECVD) method or a thermal CVD method may be used. As an example of the thermal CVD method, a metal organic chemical vapor deposition (MOCVD) method may be used.

Alternatively, the thin films included in the display device (i.e., the insulating film, the semiconductor film, the conductive film, and the like) can be formed by a method such as spin coating, dipping, spray coating, ink-jetting, dispensing, screen printing, or offset printing, or with a doctor knife, a slit coater, a roll coater, a curtain coater, or a knife coater.

When the thin films included in the display device are processed, a photolithography method or the like can be used. Alternatively, island-shaped thin films may be formed by a film formation method using a blocking mask. Alternatively, the thin films may be processed by a nano-imprinting method, a sandblasting method, a lift-off method, or the like. As the photolithography method, there are a method in which a resist mask is formed over a thin film to be processed, the thin film is processed by etching or the like, and the resist mask is removed and a method in which a photosensitive thin film is formed, and the photosensitive thin film is exposed to light and developed to be processed in a desirable shape.

As light for exposure in a photolithography method, light with an i-line (with a wavelength of 365 nm), light with a g-line (with a wavelength of 436 nm), light with an h-line (with a wavelength of 405 nm), or light in which the i-line, the g-line, and the h-line are mixed can be used. Alternatively, ultraviolet light, KrF laser light, ArF laser light, or the like can be used. Exposure may be performed by liquid immersion exposure technique. As the light for the exposure, extreme ultra-violet light (EUV) or X-rays may be used. Instead of the light for the exposure, an electron beam can be used. It is preferable to use extreme ultra-violet light, X-rays, or an electron beam because extremely minute processing can be performed. Note that in the case of performing exposure by scanning of a beam such as an electron beam, a photomask is not needed.

For etching of the thin films, dry etching, wet etching, a sandblast method, or the like can be used.

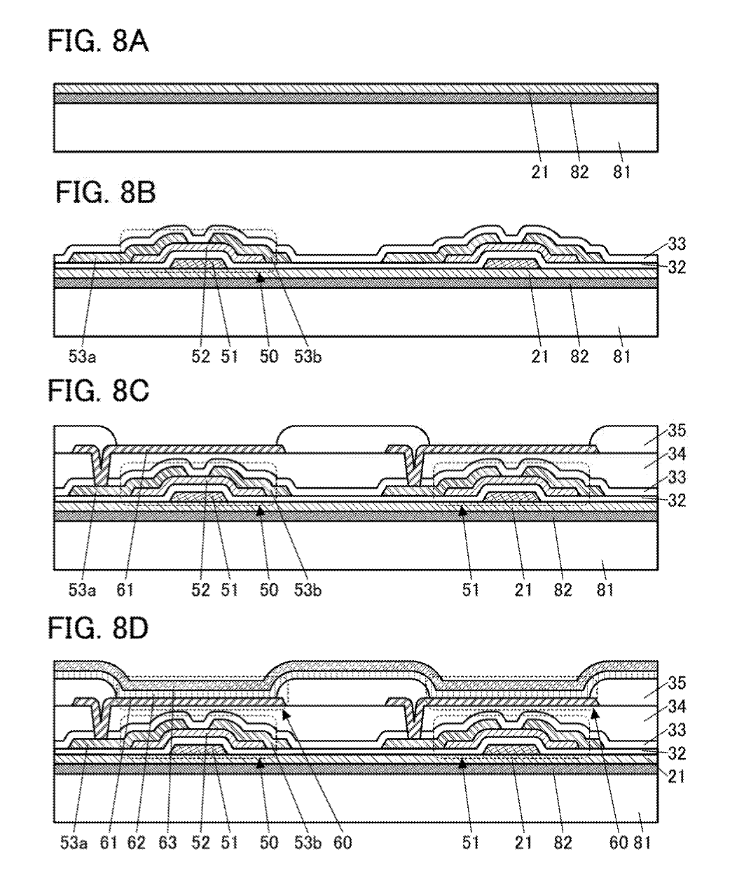

FIGS. 8A to 8D, FIGS. 9A to 9E, FIGS. 10A and 10B, and FIGS. 11A and 11B are schematic cross-sectional views each showing a stage in a manufacturing process for the display device 10.

First, a support substrate 81 is prepared. As the support substrate 81, a substrate having rigidity high enough to be easily transferred in an apparatus or between apparatuses can be used. Furthermore, a substrate which is resistant to heat in the manufacturing process is used. For example, a glass substrate with a thickness larger than or equal to 0.3 mm and smaller than or equal to 1 mm can be used.

Then, a separation layer 82 and the barrier layer 21 are formed in this order over the support substrate 81 (FIG. 8A).

The separation layer 82 can be formed using a material that allows separation at an interface between the separation layer 82 and the barrier layer 21 or in the separation layer 82.

For example, a stack of a layer containing a high-melting-point metal material, such as tungsten, and a layer containing an oxide of the metal material can be used as the separation layer 82, and a layer or a stack of layers of an inorganic insulating material such as a silicon nitride, a silicon oxide, a silicon oxynitride, a silicon nitride oxide, an aluminum oxide, or an aluminum nitride can be used as the barrier layer 21.

It is preferable to use, as the barrier layer 21, a nitrogen-containing film such as a silicon nitride film or a silicon nitride oxide film that is formed by a plasma CVD method. The barrier layer 21 formed using such a film can be dense and have an excellent barrier property.

When a stack of a tungsten layer and a tungsten oxide layer is used as the separation layer 82, separation can be performed at an interface between the tungsten layer and the tungsten oxide layer, in the tungsten oxide layer, or at an interface between the tungsten oxide layer and the barrier layer 21.

In particular, in the case where the transistor 50 and the like are formed over the separation layer 82 and the barrier layer 21, the separation layer 82 is preferably formed using a material with high heat resistance. Thus, treatment can be performed at high temperatures in a step after forming the separation layer 82, e.g., in a step of forming the transistor 50 and the surrounding insulating layer and the like. Accordingly, materials and formation methods of the transistor 50 and the like can be selected from a wider range of alternatives, and electric characteristics and reliability of the transistor 50 can be improved.

The structures of the separation layer 82 and a layer thereover to be separated are not limited thereto, and any of a variety of materials can be selected.

Then, the conductive layer 51 is formed over the barrier layer 21. The conductive layer 51 can be formed in the following manner: a conductive film is formed, a resist mask is formed, the conductive film is etched, and the resist mask is removed.

Then, the insulating layer 32 is formed.

Then, the semiconductor layer 52 is formed. The semiconductor layer 52 can be formed in the following manner: a semiconductor film is formed, a resist mask is formed, the semiconductor film is etched, and the resist mask is removed.

Then, the conductive layer 53a and the conductive layer 53b are formed. The conductive layers 53a and 53b can be formed by a method similar to that of the conductive layer 51.

At this stage, the transistor 50 is manufactured.

Then, the insulating layer 33 is formed to cover the transistor 50. The insulating layer 33 is preferably formed using an inorganic insulating material.

FIG. 8B illustrates a schematic cross-sectional view at this stage.

Then, the insulating layer 34 is formed. When a photosensitive material is used for the insulating layer 34, an opening can be formed in a part of the insulating layer 34 by a photolithography method or the like. Note that an opening may be formed by partly etching the insulating layer 34 after the insulating layer 34 is formed. The insulating layer 34 is preferably formed using an organic insulating material.

Then, an opening is formed in the insulating layer 33. The opening of the insulating layer 33 is preferably formed using the insulating layer 34 as an etching mask because the process can be simplified. Note that a resist mask formed over the insulating layer 34 may be used as a mask for the etching. Alternatively, the opening may be formed in the insulating layer 33 before the insulating layer 34 is formed.

Then, the conductive layer 61 is formed over the insulating layer 34. The conductive layer 61 can be formed by a method similar to those of the conductive layer 51 and the like. Here, a material having a property of reflecting visible light is used as the conductive layer 61 because a top-emission light-emitting element is used as the display element 60.

Then, the insulating layer 35 that covers an end portion of the conductive layer 61 is formed. The insulating layer 35 can be formed by a method similar to that for forming the insulating layer 34. The insulating layer 35 is preferably formed using an organic insulating material.

FIG. 8C illustrates a schematic cross-sectional view at this stage.

Then, the EL layer 62 and the conductive layer 63 are stacked.

The EL layer 62 can be formed by an evaporation method, a coating method, a printing method, a discharge method, or the like. In the case where the EL layer 62 is formed for each individual pixel, an evaporation method using a shadow mask such as a metal mask, an ink-jet method, or the like can be used. In the case of sharing the EL layer 62 by some pixels, an evaporation method not using a metal mask can be used.

The conductive layer 63 can be formed by an evaporation method, a sputtering method, or the like.

In addition, although not shown here, an insulating layer serving as a barrier film may be formed to cover the conductive layer 63. The insulating layer is preferably formed by a film formation method capable of forming a dense film at a low temperature, such as a sputtering method and an ALD method. The insulating layer may have a stacked-layer structure of a film containing an inorganic insulating material and a film containing an organic insulating material.

At this stage, the display element 60 is formed. FIG. 8D is a schematic cross-sectional view at this stage.

Next, a support substrate 85 is prepared. The support substrate 85 can be formed using a material similar to that of the support substrate 81.

A separation layer 86 and the insulating layer 40 are formed over the support substrate 85.

Here, a material that generates heat by absorbing light is used as the separation layer 86. For example, a metal, an alloy, or a semiconductor such as silicon can be used. Furthermore, carbon black may be used. In particular, amorphous silicon is preferably used.

Note that although the separation layer 86 is formed over an entire top surface of the support substrate 85 in the example shown here, the separation layer 86 may be processed into an island-like or lattice-like top surface shape. By processing the separation layer 86 in this manner, stress can be relieved and warpage of the support substrate 85 can be prevented.

The insulating layer 40 can be formed using an organic insulating material. It is particularly preferable to use a material having heat resistance high enough to withstand a temperature to which the material is exposed in a later step. For example, it is preferable to use an organic resin having an imide group in its structure, such as polyimide, polyamideimide, polysiloxane imide, polyimide ester, or polyetherimide because the heat resistance can be increased. Furthermore, in the case of using a polyamide imide resin, a polyimide resin, PET, or the like with a thermal expansion coefficient of 30×10⁻⁶ /K or less, the occurrence of unintentional separation due to heat applied in a later step can be prevented.

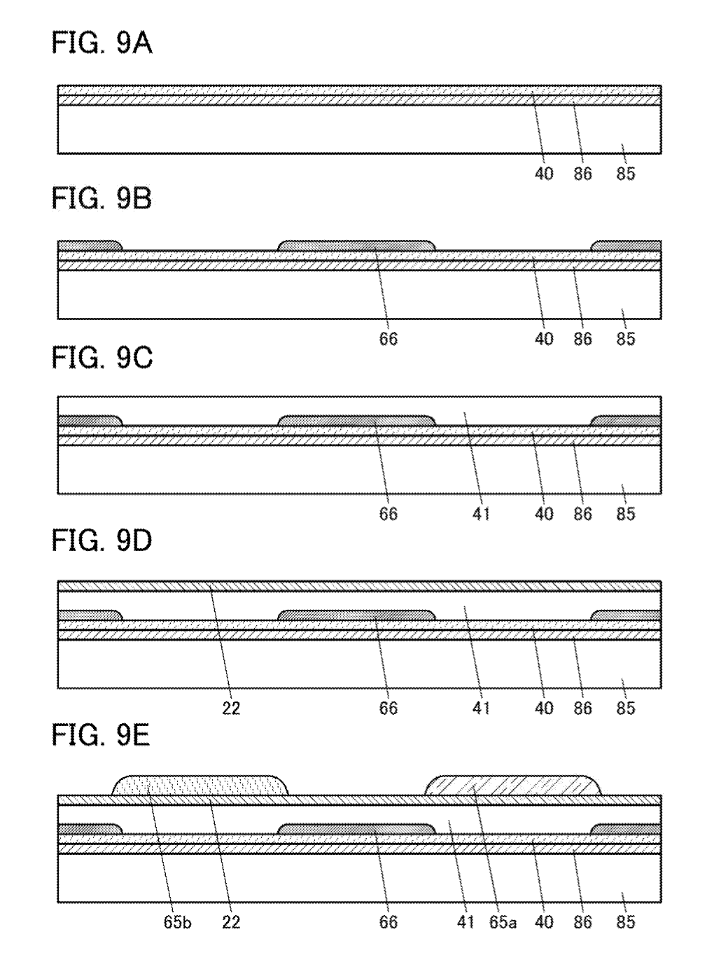

FIG. 9A illustrates a schematic cross-sectional view at this stage.

Then, the light-blocking layer 66 is formed over the insulating layer 40 (FIG. 9B). The light-blocking layer 66 can be formed using a metal film, an alloy film, or a film containing an organic resin.

Then, the insulating layer 41 is formed to cover the light-blocking layer 66 (FIG. 9C). The insulating layer 41 is preferably formed using an organic insulating material serving as a planarization layer.

Then, the barrier layer 22 is formed over the insulating layer 41 (FIG. 9D).

The barrier layer 22 can include a layer or a stack of layers of an inorganic insulating material such as a silicon nitride, a silicon oxide, a silicon oxynitride, a silicon nitride oxide, an aluminum oxide, or an aluminum nitride. The barrier layer 22 may have a stacked-layer structure of a film containing an inorganic insulating material and a film containing an organic insulating material.

The barrier layer 22 is preferably formed by a film formation method capable of forming a dense film at a low formation temperature, such as a sputtering method and an ALD method. As another example, a plasma CVD method may be used. Particularly in the case where the insulating layer 40 and the light-blocking layer 66 have high heat resistance, the barrier layer 22 is formed by a plasma CVD method and the formation temperature is set to 200° C. or higher, whereby the barrier layer 22 can be dense and have an excellent barrier property.

Then, the coloring layer 65a, the coloring layer 65b, and the like are formed over the barrier layer 22 (FIG. 9E). The coloring layer 65a and the coloring layer 65b that are formed using a photosensitive material can be processed into an island-like shape by a photolithography method or the like.

Note that the above-described steps of forming the support substrate 81 side and the above-described steps of forming the support substrate 85 side can be separately performed.

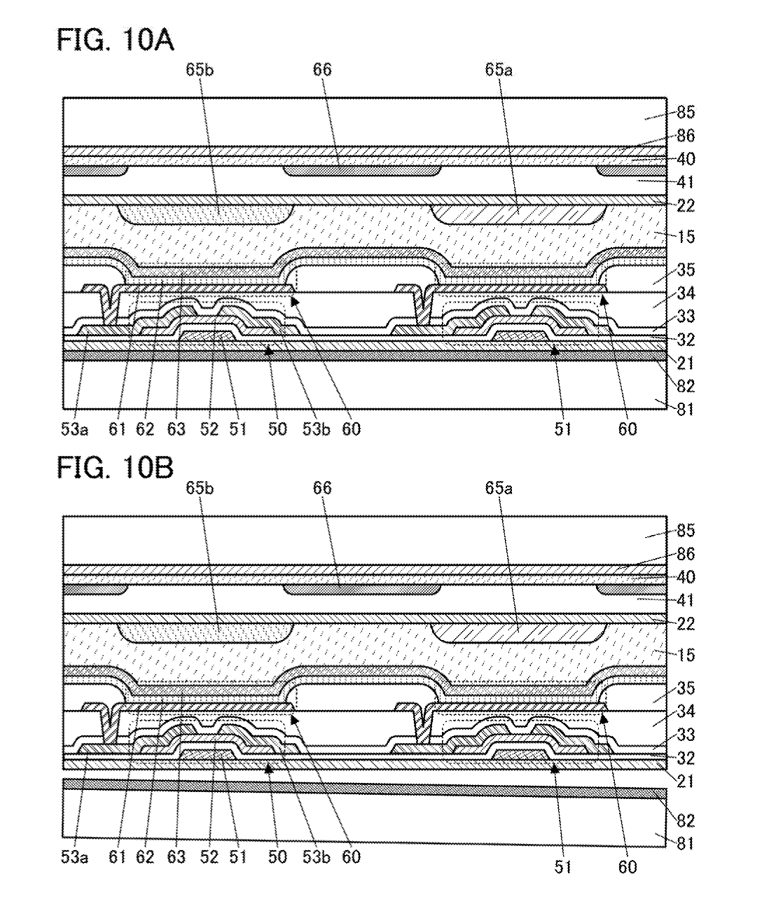

Next, the support substrate 81 and the support substrate 85 are bonded to each other using the adhesive layer 15 (FIG. 10A).

The adhesive layer 15 can be formed by a screen printing method, a dispensing method, or the like. A variety of curable resins such as a reactive curable resin, an anaerobic curable resin, a thermosetting resin, or an ultraviolet curable resin can be used as the adhesive layer 15. Alternatively, a resin that is cured when heated after pre-cured by ultraviolet light or the like may be used. Alternatively, a thermosetting and ultraviolet curable resin or the like may be used as the adhesive layer 15.

Note that in addition to the adhesive layer 15 provided in a region where pixels are arranged (also referred to as a display region), another adhesive layer may be formed in a position surrounding the display region. The portion surrounding the display region is cured first, and then, the adhesive layer 15 is cured, so that displacement of the support substrate 81 and the support substrate 85 can be prevented.

Then, separation is performed between the separation layer 82 and the barrier layer 21, whereby the support substrate 81 and the separation layer 82 are removed (FIG. 10B).

As the method for separating the support substrate 81 from the barrier layer 21, applying mechanical force, etching the separation layer, and making a liquid permeate the separation interface by dripping the liquid or soaking in the liquid are given as examples. Alternatively, separation may be performed by heating or cooling by utilizing a difference in thermal expansion coefficient of two layers which form the separation interface.

Treatment for exposing part of the separation interface is preferably performed before the separation is performed. For example, with lasers or a sharp tool, part of the barrier layer 21 on the separation layer 82 is removed. Thus, a portion in which the barrier layer 21 is removed is used as a starting point (also referred to as “separation starting point”) to perform the separation.

After the separation, part of the separation layer 82 remains on the surface of the barrier layer 21 in some cases. In that case, the remaining separation layer 82 may be removed by washing, etching, wiping, or the like. In the case where the remaining separation layer 82 does not affect the reliability or the like, the remaining separation layer 82 may be left as it is. In that case, a layer containing an element that is contained in the separation layer 82 remains between the barrier layer 21 and the adhesive layer 16, which is described later.

Then, the barrier layer 21 and the substrate 11 are bonded to each other using the adhesive layer 16. For the adhesive layer 16, a material similar to that of the adhesive layer 15 can be used.

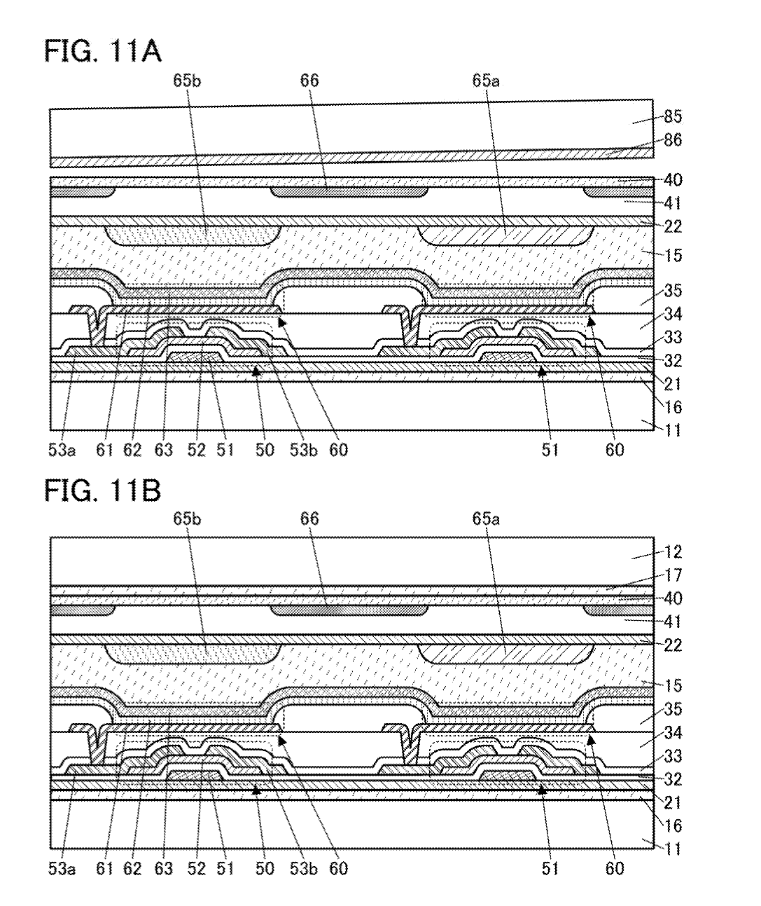

Then, separation is performed between the separation layer 86 and the insulating layer 40, whereby the support substrate 85 and the separation layer 86 are removed (FIG. 11A).

In a method for separating the support substrate 85 from the insulating layer 40, first, light with a wavelength that can be absorbed by the separation layer 86 is emitted from the support substrate 85 side. For example, a light source such as a laser or a lamp can be used to emit the light.

In the case of using a lamp as a light source, for example, a light source such as a high-pressure mercury lamp, a low-pressure mercury lamp, a metal halide lamp, a xenon lamp, or an LED can be used.

In the case of using a laser as a light source, a laser light source which outputs light with a wavelength appropriate for the intended purpose may be used. For example, one or more of the following lasers can be used: a gas laser such as an Ar laser, a Kr laser, or an excimer laser; and a solid-state laser such as a laser whose medium is single-crystal YAG, YVO₄, forsterite (Mg₂SiO₄), YAlO₃, or GdVO₄ to which one or more of Nd, Yb, Cr, Ti, Ho, Er, Tm, and Ta is added as a dopant, or a polycrystalline (ceramic) YAG, Y₂O₃, YVO₄, YAlO₃, or GdVO₄ to which one or more of Nd, Yb, Cr, Ti, Ho, Er, Tm, and Ta is added as a dopant, a glass laser, a ruby laser, an alexandrite laser, a Ti:sapphire laser, or a fiber laser. Alternatively, a second harmonic, a third harmonic, or other higher harmonics emitted from the aforementioned solid-state laser can also be used. As the excimer laser, a XeCl (308 nm) laser, a KrF (248 nm) laser, an ArF (193 nm) laser, or the like can be used.

A short time pulsed laser such as a nanosecond pulsed laser, a picosecond pulsed laser, or a femtosecond pulsed laser is appropriate for this step. With the short time pulsed laser, a high-density energy which causes a multiphoton absorption phenomenon can be applied to the irradiation target region.

In the case where amorphous silicon is used as the separation layer 86, for example, the separation layer 86 irradiated with light releases hydrogen, so that separation is likely to occur at an interface between the separation layer 86 and the insulating layer 40 or an interface between the separation layer 86 and the support substrate 85. Then, separation is performed with a physical force as in the above-described separation method, so that the insulating layer 40 and the support substrate 85 can be separated from each other.

Note that a part of the separation layer 86 remains on the insulating layer 40 side after the separation in some cases. The remaining part may be either removed or left as it is, like the separation layer 82 described above.

Note that it is possible to use a method of reducing adhesion at the interface between the separation layer 86 and the insulating layer 40 or the interface between separation layer 86 and the support substrate 85 by light irradiation or a method of forming an embrittlement layer in the separation layer 86 or the insulating layer 40 by light irradiation, for example, and a material suitable for the method can be selected, though amorphous silicon is used as the separation layer 86 in the example described here.

The separation layer 86 is not necessarily provided in the case where separation can occur as a result of reducing adhesion at the interface between the insulating layer 40 and the support substrate 85 by light irradiation. For example, a phenomenon can be used in which a part of the insulating layer 40 is crystallized by being irradiated with light and adhesion between the support substrate 85 and the insulating layer 40 is reduced accordingly.

Then, the insulating layer 40 and the substrate 12 are bonded to each other using the adhesive layer 17. For the adhesive layer 17, a material similar to that of the adhesive layer 15 can be used.

FIG. 11B illustrates a schematic cross-sectional view at this stage. FIG. 11B and FIG. 5 are the same.

Through the above steps, the display device 10 can be manufactured.

In the manufacturing method of the display device described in this example, separation on the support substrate 81 side and separation on the support substrate 85 side are performed by separation methods using different separation mechanisms. That is, the side to be separated later is separated by a method that does not cause separation until predetermined treatment (here, light irradiation) is performed. In contrast, the side to be separated earlier is separated by a method that can cause separation without such predetermined treatment or by performing different treatment (e.g., formation of a separation starting point). By using the two separation methods that use different mechanisms, a problem such as unintentional separation of the side to be separated later that may occur in the step of separating the other side can be avoided.

### Modification Example

An example to be described below shows the case where separation on the support substrate 81 side and separation on the support substrate 85 side are performed by the same separation method in Manufacturing method example.

First, the layers from the separation layer 82 to the conductive layer 63 are formed over the support substrate 81 as in Manufacturing method example.

Then, a separation layer 88 and an insulating layer 89 are formed over the support substrate 85.

The separation layer 88 has a structure similar to that of the separation layer 82, and the insulating layer 89 has a structure similar to that of the barrier layer 21.

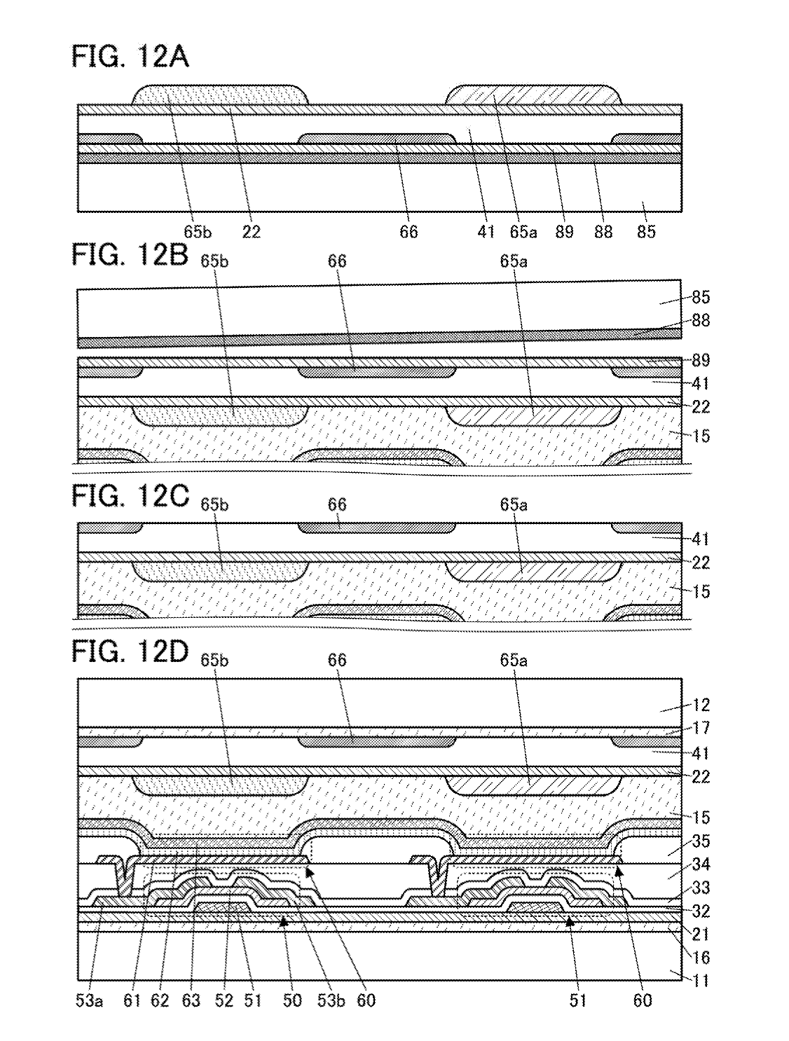

Then, the light-blocking layer 66, the insulating layer 41, the barrier layer 22, the coloring layer 65a, and the coloring layer 65b are formed over the insulating layer 89 (FIG. 12A).

Then, as in Manufacturing method example, after the support substrate 81 and the support substrate 85 are bonded to each other using the adhesive layer 15, the support substrate 81 and the separation layer 82 are removed, and the substrate 11 is bonded using the adhesive layer 16.

Then, separation is performed between the separation layer 88 and the insulating layer 89, whereby the support substrate 85 and the separation layer 88 are removed (FIG. 12B). At this time, the insulating layer 89 is left on the substrate 11 side.

In the manufacturing method example described here, the separation layer on the support substrate 81 side and the separation layer on the support substrate 85 side have the same structure. Therefore, it is important to prevent the side where separation is not intended from being separated when the first separation is performed.

In particular, in the case of a separation method in which a stacked-layer structure of a high-melting-point metal and an oxide thereof is used for a separation layer whereas a stacked-layer structure of a silicon oxide and an oxide of a silicon nitride or the like is used for a layer to be separated, separation does not occur or hardly occurs in a state where the separation interface is not exposed. Thus, by using such a separation layer and a layer to be separated, and furthermore, by selectively forming a separation starting point at the interface between the separation layer and the layer to be separated of the side where separation is intended, separation of the side where separation is unintended can be prevented.

In this method, a light irradiation step or the like is not needed. Thus, the manufacturing cost, the initial cost and the running cost of an apparatus, or the like can be reduced.

The insulating layer 89 that is left on the substrate 11 side includes an inorganic insulating material, and thus, stress is concentrated thereon easily and breakage might occur by deformation such as bending of the display device. To prevent this, the insulating layer 89 is preferably removed by etching or the like as shown in FIG. 12C. As a result of completely removing the insulating layer 89, the light-blocking layer 66 and the insulating layer 41 are positioned at the outermost surface.

Then, surfaces of the light-blocking layer 66 and the insulating layer 41 are bonded to the substrate 12 using the adhesive layer 17.

FIG. 12D is a schematic cross-sectional view at this stage. FIG. 12D differs from FIG. 5 in that the insulating layer 40 is not included.

Through the above steps, the display device 10 can be manufactured.

### Separation-Performable Structure

A method for forming an element or the like over a flexible substrate is not

An example of a manufacturing method of a display device or the like including a flexible substrate will be described below.

Here, layers each including a display element, a circuit, a wiring, an electrode, an insulating layer, optical members such as a coloring layer and a light-blocking layer, and the like are collectively referred to as an element layer. The element layer includes, for example, a display element, and may additionally include a wiring electrically connected to the display element or an element such as a transistor used in a pixel or a circuit.

In addition, here, a flexible member which supports the element layer at a stage at which the display element is completed (the manufacturing process is finished) is referred to as a substrate. For example, a substrate includes an extremely thin film with a thickness greater than or equal to 10 nm and less than or equal to 300 μm and the like.

As a method for forming an element layer over a flexible substrate provided with an insulating surface, typically, there are two methods shown below. One of them is to directly form an element layer over the flexible substrate. The other method is to form an element layer over a support substrate that is different from the flexible substrate and then to separate the element layer from the support substrate to be transferred to the substrate. Although not described in detail here, in addition to the above two methods, there is a method in which the element layer is formed over a substrate which does not have flexibility and the substrate is thinned by polishing or the like to have flexibility.

In the case where a material of the substrate can withstand heating temperature in a process for forming the element layer, it is preferable that the element layer be formed directly over the substrate, in which case a manufacturing process can be simplified. At this time, the element layer is preferably formed in a state where the substrate is fixed to the support substrate, in which case transfer thereof in an apparatus and between apparatuses can be easy.

In the case of employing the method in which the element layer is formed over the support substrate and then transferred to the substrate, first, a separation layer and an insulating layer are stacked over the support substrate, and then the element layer is formed over the insulating layer. Next, the element layer is separated from the support substrate and then transferred to the substrate. At this time, a material is selected such that separation occurs at an interface between the support substrate and the separation layer, at an interface between the separation layer and the insulating layer, or in the separation layer. With the method, it is preferable that a material having high heat resistance be used for the support substrate or the separation layer, in which case the upper limit of the temperature applied when the element layer is formed can be increased, and an element layer including a higher reliable element can be formed.

For example, a stacked layer of a layer containing a high-melting-point metal material, such as tungsten, and a layer containing an oxide of the metal material is used as the separation layer. Furthermore, a stacked layer of a plurality of layers, such as a silicon oxide layer, a silicon nitride layer, a silicon oxynitride layer, a silicon nitride oxide layer, and the like is preferably used as the insulating layer over the separation layer. Note that in this specification, oxynitride contains more oxygen than nitrogen, and nitride oxide contains more nitrogen than oxygen.

The element layer and the support substrate can be separated by applying mechanical force, by etching the separation layer, by injecting a liquid into the separation interface, or the like. Alternatively, separation may be performed by heating or cooling two layers of the separation interface by utilizing a difference in thermal expansion coefficient.

When separation is started, it is preferable that a separation starting point be formed first so that the separation proceeds from the starting point. The separation starting point can be formed, for example, by locally heating part of the insulating layer or the separation layer with laser light or the like or by physically cutting or making a hole through part of the insulating layer or the separation layer with a sharp tool.

The separation layer is not necessarily provided in the case where the separation can be performed at an interface between the support substrate and the insulating layer.

For example, glass is used for the support substrate and an organic resin such as polyimide is used for the insulating layer, in which case separation can be performed at an interface between the glass and the organic resin. The remaining organic resin such as polyimide can be used for the substrate.

Alternatively, a heat generation layer may be provided between the support substrate and the insulating layer formed of an organic resin, and separation may be performed at an interface between the heat generation layer and the insulating layer by heating the heat generation layer. As the heat generation layer, any of a variety of materials such as a material that generates heat by feeding current, a material that generates heat by absorbing light, and a material that generates heat by applying a magnetic field can be used. For example, a semiconductor, a metal, or an insulator can be selected for the heat generation layer.

The above is the description of the example of the manufacturing method.

The display device exemplified in this embodiment has high reliability because the barrier layer highly resistant to moisture is provided in a position close to the neutral plane of the display device and the barrier layer is therefore prevented from being broken by deformation such as bending. Furthermore, the display device is highly resistant to the operation of repeated folding and unfolding of the display device.

At least part of this embodiment can be implemented in combination with any of the other embodiments described in this specification as appropriate.

### Embodiment 2

In this embodiment, the flexible device of one embodiment of the present invention will be described with reference to drawings. Described in this embodiment is an example of a display device.

There is no limitation on a display element included in the display device of one embodiment of the present invention. Any of a variety of elements, such as a liquid crystal element, an optical element that utilizes MEMS, an EL element, a light-emitting element such as an LED, and an electrophoretic element, can be used as the display element.

The thickness of the display device to which one embodiment of the present invention is applied can be, for example, greater than or equal to 30 μm and less than or equal to 300 μm and is preferably greater than or equal to 50 μm and less than or equal to 200 μm, further preferably greater than or equal to 50 μm and less than or equal to 150 μm, and still further preferably greater than or equal to 50 μm and less than or equal to 100 μm. To increase the mechanical strength of the display device, the thickness of the display device is preferably greater than or equal to 50 μm. To increase the flexibility of the display device, the thickness of the display device is preferably less than or equal to 200 μm and further preferably less than or equal to 100 μm. A display device with a thickness of less than or equal to 100 μm, for example, can be bent with a radius of curvature of 1 mm, or can be repeatedly bent (e.g., more than 100000 times) with a radius of curvature of 5 mm.

### Structure Example 1

### Display Device

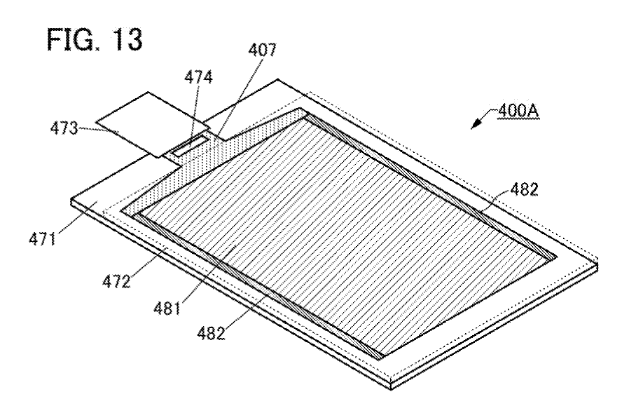

FIG. 13 is a schematic perspective view of a display device 400A of one embodiment of the present invention. In the display device 400A, a substrate 471 and a substrate 472 are bonded to each other. In FIG. 13, the substrate 472 is shown by a dashed line.

The display device 400A includes a display portion 481 and a driver circuit portion 482. A flexible printed circuit (FPC) 473 and an IC 474 are mounted on the display device 400A.

The display portion 481 includes a plurality of pixels and has a function of displaying images.

Each of the pixels includes a plurality of subpixels. For example, a subpixel exhibiting red, a subpixel exhibiting green, and a subpixel exhibiting blue can form one pixel, leading to full-color display in the display portion 481. Note that the colors exhibited by subpixels are not limited to red, green, and blue. For example, a subpixel exhibiting white, yellow, magenta, cyan, or the like may be included in a pixel. In this specification and the like, in some cases, a subpixel is referred to as a pixel.

The display device 400A may include either, both, or neither of a scan line driver circuit and a signal line driver circuit. In the case where the display device 400A includes a sensor such as a touch sensor, the display device 400A may include a sensor driver circuit. In an example described in this embodiment, a scan line driver circuit is included as the driver circuit portion 482. The scan line driver circuit has a function of outputting a scan signal to a scan line included in the display portion 481.

In the display device 400A, the IC 474 is mounted on the substrate 471 by a chip on glass (COG) method or the like. The IC 474 includes, for example, any one or more of a signal line driver circuit, a scan line driver circuit, and a sensor driver circuit.

The FPC 473 is electrically connected to the display device 400A. Through the FPC 473, a signal and power from the outside are supplied to the IC 474 and the driver circuit portion 482. In addition, a signal from the IC 474 can be output to the outside through the FPC 473.

An IC may be mounted on the FPC 473 by a chip on film (COF) method or the like. For example, an IC including any one or more of a signal line driver circuit, a scan line driver circuit, and a sensor driver circuit may be mounted on the FPC 473.

A signal and power are supplied to the display portion 481 and the driver circuit portion 482 through a wiring 407. The signal and power are input to the wiring 407 from the IC 474 or from the outside through the FPC 473.

### Cross-Sectional Structure Example

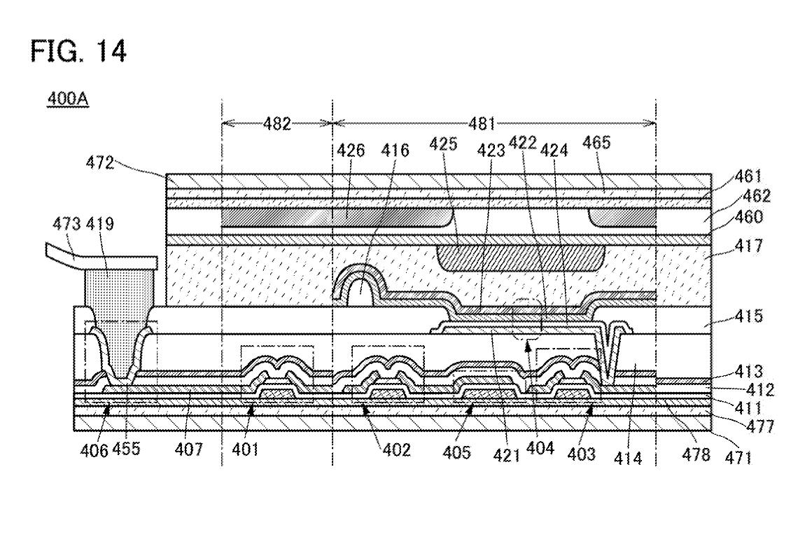

FIG. 14 is a cross-sectional view of the display device 400A, illustrating the display portion 481, the driver circuit portion 482, and the wiring 407. The display device 400A is a top-emission display device using a color filter method.

The display device 400A includes the substrate 471, a barrier layer 478, a plurality of transistors, a capacitor 405, the wiring 407, an insulating layer 411, an insulating layer 412, an insulating layer 413, an insulating layer 414, an insulating layer 415, a light-emitting element 404, a conductive layer 455, a spacer 416, an adhesive layer 417, a coloring layer 425, a light-blocking layer 426, a barrier layer 460, an insulating layer 461, an insulating layer 462, an adhesive layer 465, and the substrate 472.

The driver circuit portion 482 includes a transistor 401. The display portion 481 includes a transistor 402 and a transistor 403.

The transistors and the capacitor 405 are formed over the barrier layer 478. The substrate 471 is bonded to the barrier layer 478 using an adhesive layer 477.

Each of the transistors includes a gate, the insulating layer 411, a semiconductor layer, a source, and a drain. The gate and the semiconductor layer overlap with each other with the insulating layer 411 provided therebetween. Part of the insulating layer 411 functions as a gate insulating layer, and another part of the insulating layer 411 functions as a dielectric of the capacitor 405. A conductive layer that functions as the source or the drain of the transistor 402 also functions as one electrode of the capacitor 405.

The transistors illustrated in FIG. 14 have bottom-gate structures. The transistor in the driver circuit portion 482 and the transistor in the display portion 481 may have different structures. The driver circuit portion 482 and the display portion 481 may each include a plurality of kinds of transistors.

The capacitor 405 includes a pair of electrodes and the dielectric therebetween. The capacitor 405 includes a conductive layer that is formed using the same material and the same step as the gates of the transistors, and a conductive layer that is formed using the same material and the same step as the sources and the drains of the transistors.

The insulating layer 412, the insulating layer 413, and the insulating layer 414 are each provided to cover the transistors and the like. There is no particular limitation on the number of the insulating layers covering the transistors and the like. The insulating layer 414 functions as a planarization layer. It is preferable that at least one of the insulating layer 412, the insulating layer 413, and the insulating layer 414 be formed using a material inhibiting diffusion of impurities such as water and hydrogen. Diffusion of impurities from the outside into the transistors can be effectively inhibited, leading to improved reliability of the display device.

In FIG. 14, the insulating layer 414 is provided all over the display device. The structure illustrated in FIG. 14 is preferable because the yield of the fabrication process of a flexible device of one embodiment of the present invention can be increased.

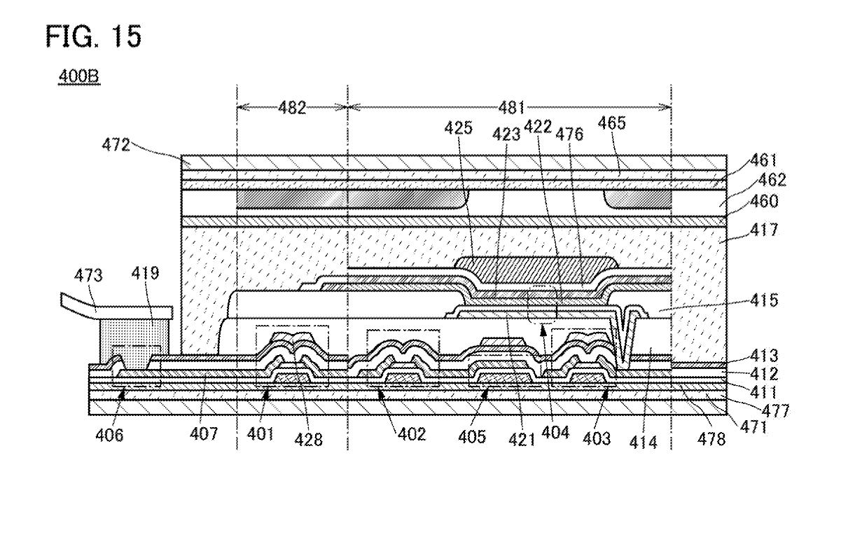

In the case of using an organic material for the insulating layer 414, impurities such as moisture might enter the light-emitting element 404 or the like from the outside of the display device through the insulating layer 414 exposed at an end portion of the display device. Deterioration of the light-emitting element 404 due to the entry of impurities can lead to deterioration of the display device. For this reason, the insulating layer 414 is preferably not positioned at the end portion of the display device, as illustrated in FIG. 15. Since an insulating layer formed using an organic material is not positioned at the end portion of the display device in the structure of FIG. 15, entry of impurities into the light-emitting element 404 can be inhibited.

The light-emitting element 404 includes an electrode 421, an EL layer 422, and an electrode 423. The light-emitting element 404 may include an optical adjustment layer 424. The light-emitting element 404 has a top-emission structure with which light is emitted to the coloring layer 425 side.

The transistors, the capacitor, the wiring, and the like are positioned so as to overlap with a light-emitting region of the light-emitting element 404; accordingly, the aperture ratio of the display portion 481 can be increased.

One of the electrode 421 and the electrode 423 functions as an anode and the other functions as a cathode. When a voltage higher than the threshold voltage of the light-emitting element 404 is applied between the electrode 421 and the electrode 423, holes are injected to the EL layer 422 from the anode side and electrons are injected to the EL layer 422 from the cathode side. The injected electrons and holes are recombined in the EL layer 422 and a light-emitting substance contained in the EL layer 422 emits light.

The electrode 421 is electrically connected to the source or the drain of the transistor 403 directly or through a conductive layer. The electrode 421 functioning as a pixel electrode is provided for each light-emitting element 404. Two adjacent electrodes 421 are electrically insulated from each other by the insulating layer 415.

The EL layer 422 contains a light-emitting substance.

The electrode 423 functioning as a common electrode is shared by a plurality of light-emitting elements 404. A fixed potential is supplied to the electrode 423.

The light-emitting element 404 overlaps with the coloring layer 425 with the adhesive layer 417 provided therebetween. The spacer 416 overlaps with the light-blocking layer 426 with the adhesive layer 417 provided therebetween. Although the spacer 416 is provided on the substrate 471 side in the structure illustrated in FIG. 14, the spacer 416 may be provided on the substrate 472 side (e.g., in a position closer to the substrate 471 than that of the barrier layer 460).

Owing to the combination of a color filter (the coloring layer 425) and a microcavity structure (the optical adjustment layer 424), light with high color purity can be extracted from the display device. The thickness of the optical adjustment layer 424 is varied depending on the color of the pixel.

The coloring layer 425 is a coloring layer that transmits light in a specific wavelength range. For example, a color filter for transmitting light in a red, green, blue, or yellow wavelength range can be used.

Note that one embodiment of the present invention is not limited to a color filter method, and a separate coloring method, a color conversion method, a quantum dot method, and the like may be employed.

The light-blocking layer 426 is provided between the adjacent coloring layers 425. The light-blocking layer 426 blocks light emitted from an adjacent light-emitting element 404 to inhibit color mixing between adjacent light-emitting elements 404. Here, the coloring layer 425 is provided such that its end portion overlaps with the light-blocking layer 426, whereby light leakage can be reduced. For the light-blocking layer 426, a material that blocks light emitted from the light-emitting element can be used. Note that it is preferable to provide the light-blocking layer 426 in a region other than the display portion 481, such as the driver circuit portion 482, in which case undesired leakage of guided light or the like can be inhibited.

The substrate 472 is bonded to the insulating layer 461 using the adhesive layer 465. The light-blocking layer 426, the insulating layer 462, the barrier layer 460, and the coloring layer 425 are provided in this order on the substrate 471 side of the insulating layer 461.

The barrier layer 478 is formed over one surface of the substrate 471. On the substrate 472 side, the barrier layer 460 is formed between the light-blocking layer 426 and the coloring layer 425. Each of the barrier layer 460 and the barrier layer 478 is preferably formed of a film highly resistant to moisture. The light-emitting element 404, the transistors, and the like are preferably provided between a pair of insulating layers which are highly resistant to moisture, in which case impurities such as water can be prevented from entering these elements, leading to higher reliability of the display device.

Examples of the insulating film highly resistant to moisture include a film containing nitrogen and silicon (e.g., a silicon nitride film and a silicon nitride oxide film) and a film containing nitrogen and aluminum (e.g., an aluminum nitride film). Alternatively, a silicon oxide film, a silicon oxynitride film, an aluminum oxide film, or the like may be used.

For example, the permeation amount of water vapor of the insulating film highly resistant to moisture is lower than or equal to 1×10⁻⁵ [g/(m²·day)], preferably lower than or equal to 1×10⁻⁶ [g/(m²·day)], further preferably lower than or equal to 1×10⁻⁷ [g/(m²·day)], still further preferably lower than or equal to 1×10⁻⁸ [g/(m²·day)].

A connection portion 406 includes the wiring 407 and the conductive layer 455. The wiring 407 is electrically connected to the conductive layer 455. The wiring 407 can be formed using the same material and the same step as those of the sources and the drains of the transistors. The conductive layer 455 is electrically connected to an external input terminal through which a signal and a potential from the outside is transmitted to the driver circuit portion 482. Here, an example in which the FPC 473 is provided as the external input terminal is described. The FPC 473 is electrically connected to the conductive layer 455 through a connection layer 419.

The connection layer 419 can be formed using any of various kinds of anisotropic conductive films (ACF), anisotropic conductive pastes (ACP), and the like.

The above is the description of Structure example 1.

### Structure Example 2

FIG. 15 is a cross-sectional view of a display device 400B. The display device 400B is a top-emission display device using a color filter method. Note that a perspective view of the display device 400B is similar to that of the display device 400A shown in FIG. 13. In the structure example below, components similar to those in the above structure example will not be described in detail.

The display device 400B includes an insulating layer 476 that is in contact with the light-emitting element 404. The insulating layer 476 covers an end portion of the electrode 423. The insulating layer 476 serves as a sealing layer for the light-emitting element 404. The coloring layer 425 is provided over the insulating layer 476. The insulating layer 476, the coloring layer 425, and the like need not be provided for the substrate 472, and thus, a material used for the substrate 472 can be selected from a wider range of alternatives.

In the example shown here, the transistor 401 and the transistor 403 each include a conductive layer 428 that serves as a second gate. In this structure, by supplying different potentials to two gates of each of the transistors, the threshold voltage of the transistors can be controlled. By supplying the same potential to the two gates of each of the transistors, the field-effect mobility of the transistors can be increased. Such transistors can have higher field-effect mobility and thus have higher on-state current than other transistors. Consequently, a circuit capable of high-speed operation can be obtained. Furthermore, the area occupied by a circuit can be reduced. The use of the transistors having high on-state current can reduce signal delay in wirings and can reduce display luminance variation even in a display device in which the number of wirings is increased because of an increase in size or resolution.

In the example shown here, the capacitor 405 includes the conductive layer 428. The capacitance of the capacitor 405 having such a structure can be increased.

The above is the description of Structure example 2.

### Components

The above components will be described below. Note that some of the components already described in the above embodiments and the like are not described here. The materials described below can also be used as appropriate for a display device (including a touch panel) and the like described in the following embodiments.

### Substrate

A flexible substrate can be used as the substrate included in the display device. The substrate on the side from which light from the display element is extracted is formed using a material transmitting the light. For example, a material such as glass, quartz, ceramics, sapphire, or an organic resin can be used.

The weight and thickness of the display device can be reduced by using a thin substrate. A flexible display device can be obtained by using a substrate that is thin enough to have flexibility.

Since the substrate through which light is not extracted does not need to have a light-transmitting property, a metal substrate or the like can be used in addition to the above-mentioned substrates.

### Transistor

The transistor includes a conductive layer serving as a gate, a semiconductor layer, a conductive layer serving as a source, a conductive layer serving as a drain, and an insulating layer serving as a gate insulating layer.

Note that there is no particular limitation on the structure of the transistor included in the display device of one embodiment of the present invention. For example, a planar transistor, a staggered transistor, or an inverted staggered transistor can be used. A top-gate transistor or a bottom-gate transistor may also be used. Here, a staggered transistor has a structure in which a gate electrode is located above a semiconductor layer and a source electrode and a drain electrode are located below the semiconductor layer. Meanwhile, an inverted staggered transistor has a structure in which a gate electrode is located below a semiconductor layer and a source electrode and a drain electrode are located above the semiconductor layer. Gate electrodes may be provided above and below a channel.

There is no particular limitation on the crystallinity of a semiconductor material used for the transistors, and an amorphous semiconductor or a semiconductor having crystallinity (a microcrystalline semiconductor, a polycrystalline semiconductor, a single crystal semiconductor, or a semiconductor partly including crystal regions) may be used. It is preferable that a semiconductor having crystallinity be used, in which case deterioration of the transistor characteristics can be suppressed.

As a semiconductor material used for the transistor, for example, an element of Group 14 (e.g., silicon or germanium), a compound semiconductor, or an oxide semiconductor can be used. Typically, a semiconductor containing silicon, a semiconductor containing gallium arsenide, an oxide semiconductor containing indium, or the like can be used.

In particular, an oxide semiconductor having a wider band gap than silicon is preferably used. A semiconductor material having a wider band gap and a lower carrier density than silicon is preferably used because off-state current of the transistor can be reduced.

For example, the oxide semiconductor preferably contains at least indium (In) or zinc (Zn). The oxide semiconductor more preferably includes an In—M—Zn-based oxide (M is a metal such as Al, Ti, Ga, Ge, Y, Zr, Sn, La, Ce, or Hf).

For the semiconductor layer, it is particularly preferable to use an oxide semiconductor film including a plurality of crystal parts whose c-axes are aligned substantially perpendicular to a surface on which the semiconductor layer is formed or the top surface of the semiconductor layer and in which a grain boundary is not observed between adjacent crystal parts.

There is no grain boundary in such an oxide semiconductor; therefore, generation of a crack in an oxide semiconductor film which is caused by stress when a display device is bent is prevented. Therefore, such an oxide semiconductor can be suitably used for a flexible display device which is used in a bent state, or the like.

Moreover, the use of such an oxide semiconductor with crystallinity for the semiconductor layer makes it possible to provide a highly reliable transistor with a small change in electrical characteristics.

A transistor with an oxide semiconductor whose band gap is larger than the band gap of silicon has a low off-state current and therefore can hold charges stored in a capacitor that is series-connected to the transistor for a long time. When such a transistor is used for a pixel, operation of a driver circuit can be stopped while a gray scale of each pixel is maintained. As a result, a display device with extremely low power consumption can be obtained.

Alternatively, silicon is preferably used as a semiconductor in which a channel of a transistor is formed. Although amorphous silicon may be used as silicon, silicon having crystallinity is particularly preferable. For example, microcrystalline silicon, polycrystalline silicon, single crystal silicon, or the like is preferably used. In particular, polycrystalline silicon can be formed at a lower temperature than single crystal silicon and has higher field effect mobility and higher reliability than amorphous silicon. When such a polycrystalline semiconductor is used for a pixel, the aperture ratio of the pixel can be improved. Even in the case of a display device with an extremely high definition, a scan line driver circuit and a signal line driver circuit can be formed over a substrate over which pixels are formed, and the number of components of an electronic device can be reduced.

Alternatively, transistors including different semiconductors may be provided. For example, a transistor including polycrystalline silicon and a transistor including an oxide semiconductor may be provided in combination. At this time, polycrystalline silicon is preferably used for a transistor to which large current needs to be supplied, such as a transistor in a driver circuit or a transistor for current control. Furthermore, an oxide semiconductor is preferably used for a transistor which holds electric charge accumulated in a capacitor or the like that is series-connected to the transistor, such as a switching transistor in a pixel.

### Conductive Layer

As materials for a gate, a source, and a drain of a transistor, and a conductive layer such as a wiring or an electrode included in a display device, any of metals such as aluminum, titanium, chromium, nickel, copper, yttrium, zirconium, molybdenum, silver, tantalum, and tungsten, or an alloy containing any of these metals as its main component can be used. A single-layer structure or multi-layer structure including a film containing any of these materials can be used. For example, the following structures can be given: a single-layer structure of an aluminum film containing silicon, a two-layer structure in which an aluminum film is stacked over a titanium film, a two-layer structure in which an aluminum film is stacked over a tungsten film, a two-layer structure in which a copper film is stacked over a copper-magnesium-aluminum alloy film, a two-layer structure in which a copper film is stacked over a titanium film, a two-layer structure in which a copper film is stacked over a tungsten film, a three-layer structure in which a titanium film or a titanium nitride film, an aluminum film or a copper film, and a titanium film or a titanium nitride film are stacked in this order, and a three-layer structure in which a molybdenum film or a molybdenum nitride film, an aluminum film or a copper film, and a molybdenum film or a molybdenum nitride film are stacked in this order. Note that an oxide such as indium oxide, tin oxide, or zinc oxide may be used. Copper containing manganese is preferably used because the controllability of a shape by etching is increased.

As a light-transmitting conductive material, a conductive oxide such as indium oxide, indium tin oxide, indium zinc oxide, zinc oxide, or zinc oxide to which gallium is added, or graphene can be used. Alternatively, a metal material such as gold, silver, platinum, magnesium, nickel, tungsten, chromium, molybdenum, iron, cobalt, copper, palladium, or titanium, or an alloy material containing any of these metal materials can be used. Alternatively, a nitride of the metal material (e.g., titanium nitride) or the like may be used. In the case of using the metal material or the alloy material (or the nitride thereof), the thickness is set small enough to be able to transmit light. Alternatively, a stack of any of the above materials can be used as the conductive layer. For example, a stacked film of indium tin oxide and an alloy of silver and magnesium is preferably used because the conductivity can be increased. They can also be used for conductive layers such as a variety of wirings and electrodes included in a display device, and conductive layers (e.g., conductive layers serving as a pixel electrode or a common electrode) included in a display element.

### Insulating Layer

Examples of an insulating material that can be used for the insulating layers include a resin such as acrylic or epoxy resin, a resin having a siloxane bond, and an inorganic insulating material such as silicon oxide, silicon oxynitride, silicon nitride oxide, silicon nitride, or aluminum oxide.

### Light-Emitting Element

As the light-emitting element, a self-luminous element can be used, and an element whose luminance is controlled by current or voltage is included in the category of the light-emitting element. For example, a light-emitting diode (LED), an organic EL element, an inorganic EL element, or the like can be used.

The light-emitting element may be a top emission, bottom emission, dual emission light-emitting element, or the like. A conductive film that transmits visible light is used as the electrode through which light is extracted. A conductive film that reflects visible light is preferably used as the electrode through which light is not extracted.

The EL layer includes at least a light-emitting layer. In addition to the light-emitting layer, the EL layer may further include a layer containing any of a substance with a high hole-injection property, a substance with a high hole-transport property, a hole-blocking material, a substance with a high electron-transport property, a substance with a high electron-injection property, a substance with a bipolar property (a substance with a high electron- and hole-transport property), and the like.

Either a low molecular compound or a high molecular compound can be used for the EL layer, and an inorganic compound may also be included. The layers included in the EL layer can be formed by any of the following methods: an evaporation method (including a vacuum evaporation method), a transfer method, a printing method, an inkjet method, a coating method, and the like.

When a voltage higher than the threshold voltage of the light-emitting element is applied between the anode and the cathode, holes are injected to the EL layer from the anode side and electrons are injected to the EL layer from the cathode side. The injected electrons and holes are recombined in the EL layer, so that a light-emitting substance contained in the EL layer emits light.

In the case where a light-emitting element emitting white light is used as the light-emitting element, the EL layer preferably contains two or more kinds of light-emitting substances. For example, light-emitting substances are selected so that two or more light-emitting substances emit complementary colors to obtain white light emission. Specifically, it is preferable to contain two or more light-emitting substances selected from light-emitting substances emitting light of red (R), green (G), blue (B), yellow (Y), orange (O), and the like and light-emitting substances emitting light containing two or more of spectral components of R, G, and B. The light-emitting element preferably emits light with a spectrum having two or more peaks in the wavelength range of a visible light region (e.g., 350 nm to 750 nm). An emission spectrum of a material emitting light having a peak in the wavelength range of a yellow light preferably includes spectral components also in the wavelength range of a green light and a red light.

A light-emitting layer containing a light-emitting material emitting light of one color and a light-emitting layer containing a light-emitting material emitting light of another color are preferably stacked in the EL layer. For example, the plurality of light-emitting layers in the EL layer may be stacked in contact with each other or may be stacked with a region not including any light-emitting material therebetween. For example, between a fluorescent layer and a phosphorescent layer, a region containing the same material as one in the fluorescent layer or phosphorescent layer (for example, a host material or an assist material) and no light-emitting material may be provided. This facilitates the manufacture of the light-emitting element and reduces the drive voltage.

The light-emitting element may be a single element including one EL layer or a tandem element in which a plurality of EL layers are stacked with a charge generation layer provided therebetween.

The conductive film that transmits visible light can be formed using, for example, indium oxide, indium tin oxide, indium zinc oxide, zinc oxide, or zinc oxide to which gallium is added. Alternatively, a film of a metal material such as gold, silver, platinum, magnesium, nickel, tungsten, chromium, molybdenum, iron, cobalt, copper, palladium, or titanium; an alloy containing any of these metal materials; or a nitride of any of these metal materials (e.g., titanium nitride) can be used when formed thin so as to have a light-transmitting property. Alternatively, a stacked film of any of the above materials can be used as the conductive layer. For example, a stacked film of indium tin oxide and an alloy of silver and magnesium is preferably used, in which case conductivity can be increased. Further alternatively, graphene or the like may be used.

For the conductive film that reflects visible light, for example, a metal material such as aluminum, gold, platinum, silver, nickel, tungsten, chromium, molybdenum, iron, cobalt, copper, or palladium, or an alloy including any of these metal materials can be used. Lanthanum, neodymium, germanium, or the like may be added to the metal material or the alloy. Alternatively, an alloy containing aluminum (an aluminum alloy) such as an alloy of aluminum and titanium, an alloy of aluminum and nickel, or an alloy of aluminum and neodymium may be used. Alternatively, an alloy containing silver such as an alloy of silver and copper, an alloy of silver and palladium, or an alloy of silver and magnesium may be used. An alloy of silver and copper is preferable because of its high heat resistance. Furthermore, when a metal film or a metal oxide film is stacked in contact with an aluminum film or an aluminum alloy film, oxidation can be suppressed. Examples of a material for the metal film or the metal oxide film include titanium and titanium oxide. Alternatively, the conductive film having a property of transmitting visible light and a film containing any of the above metal materials may be stacked. For example, a stack of silver and indium tin oxide, a stack of an alloy of silver and magnesium and indium tin oxide, or the like can be used.

The electrodes may each be formed by an evaporation method or a sputtering method. Alternatively, a discharge method such as an inkjet method, a printing method such as a screen printing method, or a plating method may be used.

Note that the aforementioned light-emitting layer and layers containing a substance with a high hole-injection property, a substance with a high hole-transport property, a substance with a high electron-transport property, a substance with a high electron-injection property, and a substance with a bipolar property may include an inorganic compound such as a quantum dot or a high molecular compound (e.g., an oligomer, a dendrimer, and a polymer). For example, when used for the light-emitting layer, the quantum dot can serve as a light-emitting material.

The quantum dot may be a colloidal quantum dot, an alloyed quantum dot, a core-shell quantum dot, a core quantum dot, or the like. The quantum dot containing elements belonging to Groups 12 and 16, elements belonging to Groups 13 and 15, or elements belonging to Groups 14 and 16, may be used. Alternatively, the quantum dot containing an element such as cadmium, selenium, zinc, sulfur, phosphorus, indium, tellurium, lead, gallium, arsenic, or aluminum may be used.

### Adhesive Layer

As the adhesive layer, a variety of curable adhesives such as a reactive curable adhesive, a thermosetting adhesive, an anaerobic adhesive, and a photocurable adhesive such as an ultraviolet curable adhesive can be used. Examples of these adhesives include an epoxy resin, an acrylic resin, a silicone resin, a phenol resin, a polyimide resin, an imide resin, a polyvinyl chloride (PVC) resin, a polyvinyl butyral (PVB) resin, an ethylene vinyl acetate (EVA) resin, and the like. Alternatively, a two-component-mixture-type resin may be used. Further alternatively, an adhesive sheet or the like may be used.

Furthermore, the resin may include a drying agent. For example, a substance that adsorbs water by chemical adsorption, such as oxide of an alkaline earth metal (e.g., calcium oxide or barium oxide), can be used. Alternatively, a substance that adsorbs water by physical adsorption, such as zeolite or silica gel, may be used. The drying agent is preferably included because it can prevent impurities such as water from entering the element, thereby improving the reliability of the display device.

In addition, it is preferable to mix a filler with a high refractive index or light-scattering member into the resin, in which case light extraction efficiency can be enhanced. For example, titanium oxide, barium oxide, zeolite, zirconium, or the like can be used.

### Connection Layer

As the connection layers, an anisotropic conductive film (ACF), an anisotropic conductive paste (ACP), or the like can be used.

### Coloring Layer

Examples of a material that can be used for the coloring layers include a metal material, a resin material, and a resin material containing a pigment or dye.

### Light-Blocking Layer

Examples of a material that can be used for the light-blocking layer include carbon black, titanium black, a metal, a metal oxide, and a composite oxide containing a solid solution of a plurality of metal oxides. The light-blocking layer may be a film containing a resin material or a thin film of an inorganic material such as a metal. Stacked films containing the material of the coloring layer can also be used for the light-blocking layer. For example, a stacked-layer structure of a film containing a material of a coloring layer which transmits light of a certain color and a film containing a material of a coloring layer which transmits light of another color can be employed. It is preferable that the coloring layer and the light-blocking layer be formed using the same material because the same manufacturing apparatus can be used and the process can be simplified.

The above is the description of each of the components.

At least part of this embodiment can be implemented in combination with any of the other embodiments described in this specification as appropriate.

### Embodiment 3

In this embodiment, structure examples of an input device (touch sensor) applicable to the display device of one embodiment of the present invention, an input/output device (touch panel) that is an example of the display device of one embodiment of the present invention, and the like will be described.

Note that in this specification and the like, a display panel as one embodiment of the display device has a function of displaying (outputting) an image or the like on (to) a display surface; hence, the display panel is one embodiment of an output device.

In this specification and the like, a structure in which a connector such as an FPC or a tape carrier package (TCP) is attached to a substrate of a display panel, or a structure in which an IC is mounted on a substrate by a COG method or the like is referred to as a display panel module or a display module, or simply referred to as a display panel or the like in some cases.

In this specification and the like, a touch sensor has a function of sensing contact, press, approach, or the like of an object such as a finger or a stylus. In addition, the touch sensor may have a function of sensing the positional information of the object. Thus, the touch sensor is one embodiment of an input device.

In this specification and the like, a substrate provided with a touch sensor is referred to as a touch sensor panel or simply referred to as a touch sensor or the like in some cases. Furthermore, in this specification and the like, a structure in which a connector such as an FPC or a TCP is attached to a substrate of a touch sensor panel, or a structure in which an IC is mounted on a substrate by a COG method or the like is referred to as a touch sensor panel module, a touch sensor module, or a sensor module, or simply referred to as a touch sensor or the like in some cases.

Note that in this specification and the like, a touch panel which is one embodiment of the display device has a function of displaying (outputting) an image or the like on (to) a display surface and a function as a touch sensor capable of sensing contact, press, approach, or the like of an object such as a finger or a stylus on or to the display surface. Thus, the touch panel is one embodiment of an input/output device.

A touch panel can be referred to, for example, a display panel (or a display device) with a touch sensor or a display panel (or a display device) having a touch sensor function.

A touch panel can include a display panel and a touch sensor panel. Alternatively, a touch panel can have a function of a touch sensor inside a display panel.

In this specification and the like, a structure in which a connector such as an FPC or a TCP is attached to a substrate of a touch panel, or a structure in which an IC is mounted on a substrate by a COG method or the like is referred to as a touch panel module or a display module, or simply referred to as a touch panel or the like in some cases.

### Structure Example of Touch Sensor

A structure example of the input device (touch sensor) will be described below with reference to drawings.

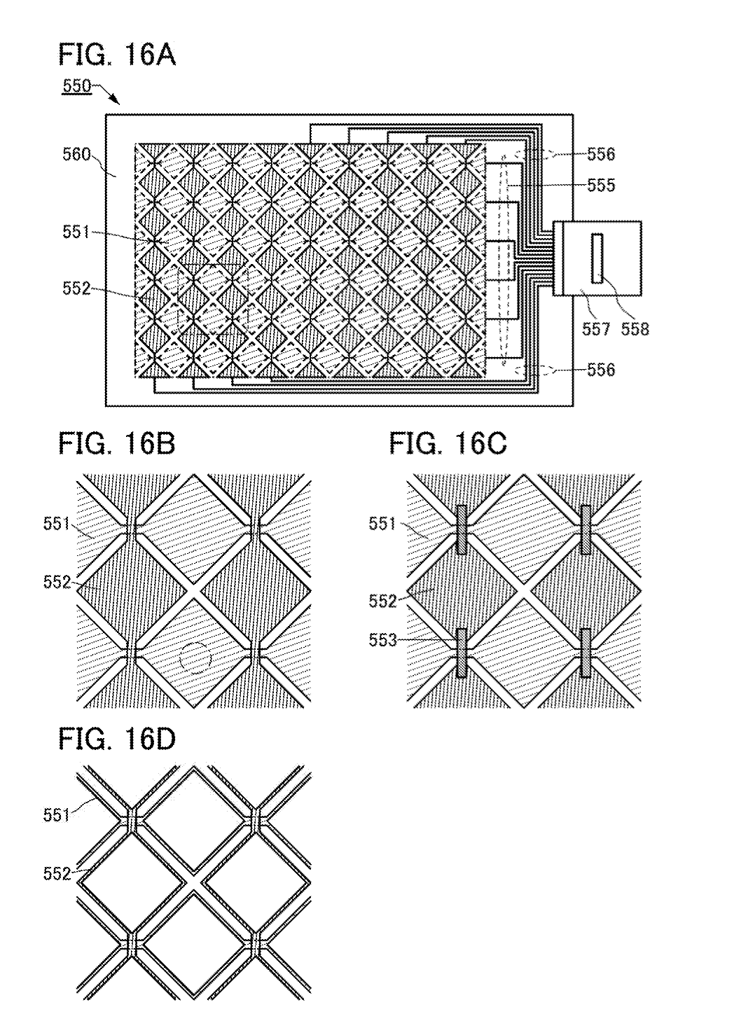

FIG. 16A is a schematic top view of an input device 550. The input device 550 includes a plurality of conductive layers 551, a plurality of conductive layers 552, a plurality of wirings 555, and a plurality of wirings 556 over a substrate 560. The substrate 560 is provided with an FPC 557 which is electrically connected to each of the plurality of conductive layers 551 and the plurality of conductive layers 552. FIG. 16A illustrates an example in which the FPC 557 is provided with an IC 558.

FIG. 16B is an enlarged view of a region surrounded by a dashed dotted line in FIG. 16A. The conductive layers 551 are each in the form of a row of rhombic electrode patterns arranged in a lateral direction. The row of rhombic electrode patterns are electrically connected to each other. The conductive layers 552 are also each in the form of a row of rhombic electrode patterns arranged in a longitudinal direction, and the row of rhombic electrode patterns are electrically connected. Part of the conductive layer 551 and part of the conductive layer 552 overlap and intersect with each other. At this intersection portion, an insulator is sandwiched in order to avoid an electrical short-circuit between the conductive layer 551 and the conductive layer 552.

As illustrated in FIG. 16C, a plurality of island-shape rhombic conductive layers 552 may be connected to each other by conductive layers 553. The island-shape rhombic conductive layers 552 are arranged in the longitudinal direction, and two adjacent conductive layers 552 are electrically connected to each other by the conductive layer 553. Such a structure allows the conductive layers 551 and the conductive layers 552 to be formed at the same time by processing the same conductive film. This can prevent variations in the thickness of these conductive layer, and can prevent the resistance value and the light transmittance of each electrode from varying from place to place. Note that although the conductive layers 552 include the conductive layers 553 here, the conductive layers 551 may have such a structure.

As illustrated in FIG. 16D, a design in which rhombic electrode patterns of the conductive layers 551 and 552 illustrated in FIG. 16B are hollowed out and only edge portions are left may be used. At that time, when the conductive layers 551 and 552 are narrow enough to be invisible to the users, the conductive layers 551 and 552 can be formed using a light-blocking material such as a metal or an alloy, as will be described later. In addition, either the conductive layers 551 or the conductive layers 552 illustrated in FIG. 16D may include the above conductive layers 553.

One of the conductive layers 551 is electrically connected to one of the wirings 555. One of the conductive layers 552 is electrically connected to one of the wirings 556. Here, either one of the conductive layers 551 and 552 corresponds to a row wiring, and the other corresponds to a column wiring.

The IC 558 has a function of driving the touch sensor. A signal output from the IC 558 is supplied to either of the conductive layers 551 and 552 through the wirings 555 or 556. A current (or a potential) flowing to either of the conductive layers 551 and 552 is input to the IC 558 through the wirings 555 or 556.

When a touch panel is formed in such a manner that the input device 550 is stacked over a display screen of the display panel, a light-transmitting conductive material is preferably used for the conductive layers 551 and 552. In the case where a light-transmitting conductive material is used for the conductive layers 551 and 552 and light from the display panel is extracted through the conductive layers 551 and 552, it is preferable that a conductive film containing the same conductive material be arranged between the conductive layers 551 and 552 as a dummy pattern. Part of a space between the conductive layers 551 and 552 is filled with the dummy pattern, which can reduce variation in light transmittance. As a result, unevenness in luminance of light transmitted through the input device 550 can be reduced.

As the light-transmitting conductive material, a conductive oxide such as indium oxide, indium tin oxide, indium zinc oxide, zinc oxide, or zinc oxide to which gallium is added can be used. Note that a film containing graphene may be used as well. The film including graphene can be formed, for example, by reducing a film containing graphene oxide. As a reducing method, a method with application of heat or the like can be employed.

Alternatively, a metal film or an alloy film which is thin enough to have a light-transmitting property can be used. For example, a metal such as gold, silver, platinum, magnesium, nickel, tungsten, chromium, molybdenum, iron, cobalt, copper, palladium, or titanium, or an alloy containing any of these metals can be used. Alternatively, a nitride of the metal or the alloy (e.g., titanium nitride), or the like may be used. Alternatively, a stacked film in which two or more of conductive films containing the above materials are stacked may be used.

For the conductive layers 551 and 552, a conductive film that is processed to be narrow enough to be invisible to the users may be used. Such a conductive film is processed into a lattice shape (a mesh shape), for example, which makes it possible to achieve both high conductivity and high visibility of the display device. It is preferable that the conductive film have a portion in which the width is greater than or equal to 30 nm and less than or equal to 100 μm, preferably greater than or equal to 50 nm and less than or equal to 50 μm, and further preferably greater than or equal to 50 nm and less than or equal to 20 μm. In particular, the conductive film having the pattern width of 10 μm or less is hardly visible to the users, which is preferable.

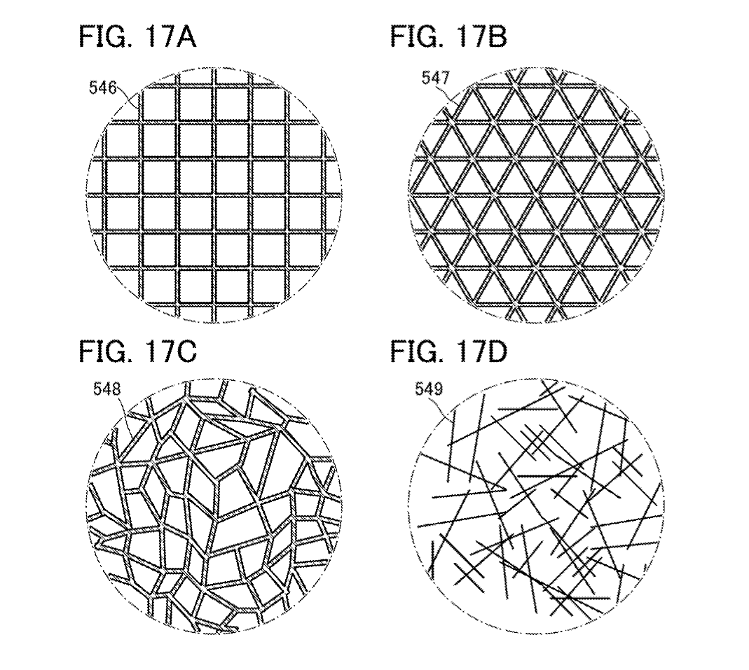

FIGS. 17A to 17D each illustrate an example of an enlarged schematic diagram of part of the conductive layer 551 or the conductive layer 552. FIG. 17A illustrates an example where a lattice-shape conductive film 546 is used. The conductive film 546 is preferably placed so as not to overlap with the display element included in the display device because light from the display device is not blocked. In that case, it is preferable that the direction of the lattice be the same as the direction of the display element arrangement and that the pitch of the lattice be an integer multiple of the pitch of the display element arrangement.

FIG. 17B illustrates an example of a lattice-shape conductive film 547, which is processed so as to be provided with triangle openings. Such a structure makes it possible to further reduce the resistance compared with the structure illustrated in FIG. 17A.

In addition, a conductive film 548, which has an irregular pattern shape, may be used as illustrated in FIG. 17C. Such a structure can prevent generation of moire when overlapping with the display portion of the display device.

Conductive nanowires may be used for the conductive layers 551 and 552. FIG. 17D illustrates an example where nanowires 549 are used. The nanowires 549 are dispersed at appropriate density so as to be in contact with the adjacent nanowires, which can form a two-dimensional network; therefore, the nanowires 549 can function as a conductive film with extremely high light-transmitting property. For example, nanowires which have a mean diameter of greater than or equal to 1 nm and less than or equal to 100 nm, preferably greater than or equal to 5 nm and less than or equal to 50 nm, and further preferably greater than or equal to 5 nm and less than or equal to 25 nm, can be used. As the nanowire 549, a metal nanowire such as an Ag nanowire, a Cu nanowire, or an Al nanowire, a carbon nanotube, or the like can be used. In the case of using an Ag nanowire, a light transmittance of 89% or more and a sheet resistance of 40 ohms per square or more and 100 ohms per square or less can be achieved.

The above is the description of the structure example of the touch sensor.

### Structure Example 1 of Touch Panel

There is no particular limitation on a sensor element included in the touch panel of one embodiment of the present invention. Note that a variety of sensors that can sense proximity or touch of a sensing target such as a finger or a stylus can be used as the sensor element.

For example, a variety of types such as a capacitive type, a resistive type, a surface acoustic wave type, an infrared type, an optical type, and a pressure-sensitive type can be used for the sensor.

In this embodiment, a touch panel including a capacitive sensor element will be described as an example.

Examples of the capacitive touch sensor include a surface capacitive touch sensor and a projected capacitive touch sensor. Examples of the projected capacitive touch sensor include a self-capacitive touch sensor and a mutual capacitive touch sensor. The use of a mutual capacitive type is preferable because multiple points can be sensed simultaneously.

The touch panel of one embodiment of the present invention can have any of a variety of structures, including a structure in which a display device and a sensor element that are separately formed are bonded to each other and a structure in which an electrode and the like included in a sensor element are provided on one or both of a substrate supporting a display element and a counter substrate.

### Structure Example

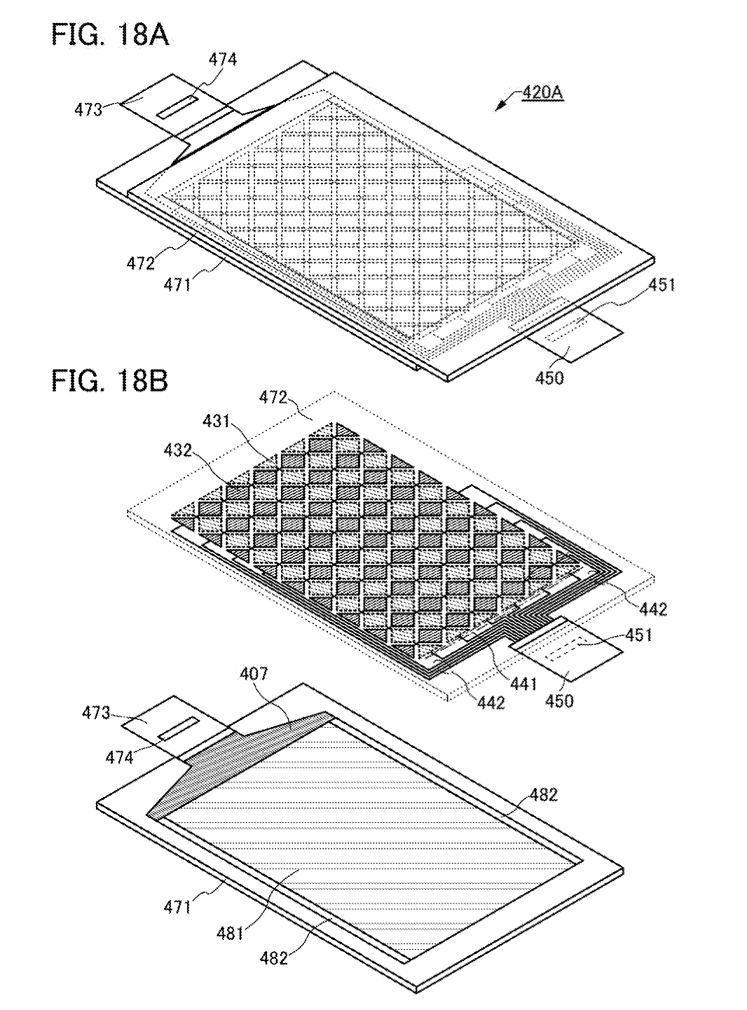

FIG. 18A is a schematic perspective view of a touch panel 420A. FIG. 18B is a developed view of the schematic perspective view of FIG. 18A. Note that only typical components are illustrated for simplicity. In FIG. 18B, some components (such as the substrate 472) are illustrated only in dashed outline.

In the touch panel 420A, the substrate 472 provided with electrodes (an electrode 431, an electrode 432, and the like) for forming a touch sensor and the substrate 471 provided with a display element and the like overlap with each other.

The touch panel 420A includes the substrate 471 and the substrate 472 that are provided to face each other. The touch panel 420A includes the display portion 481 and the driver circuit portion 482. The wiring 407 and the like are provided over the substrate 471. The FPC 473 is electrically connected to the wiring 407. The IC 474 is provided for the FPC 473.

The wiring 407 has a function of supplying a signal or power to the display portion 481 or the driver circuit portion 482. The signal or power is input from the outside or the IC 474 to the wiring 407 through the FPC 473. The touch panel 420A shown in FIG. 18A can also be referred to as a touch panel module because the FPC 473 and the IC 474 are mounted.

### Cross-Sectional Structure Example

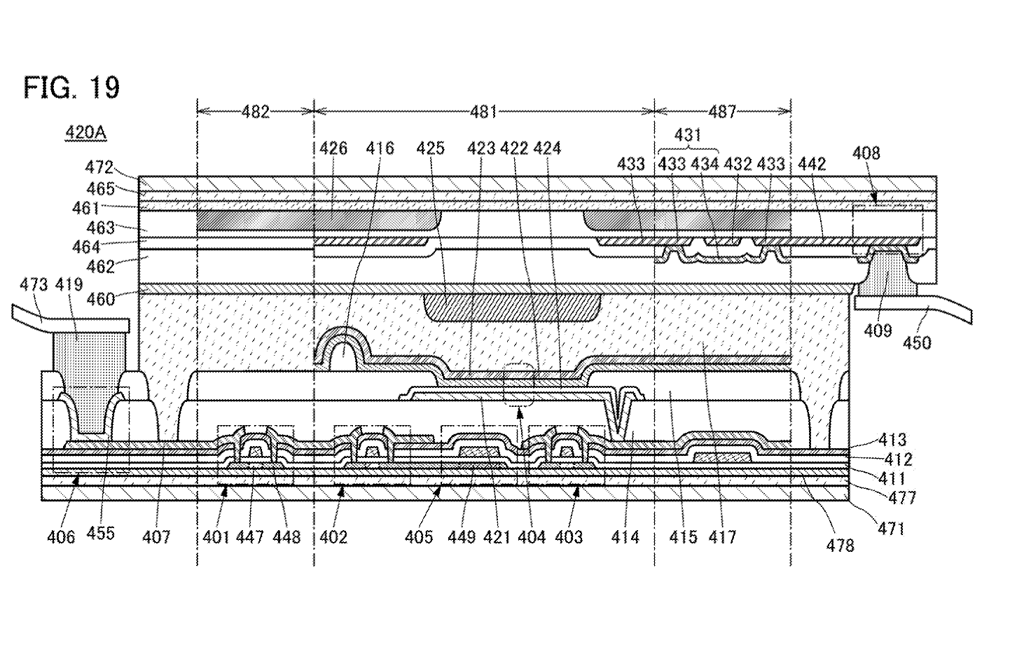

FIG. 19 illustrates an example of a cross-sectional view of the touch panel 420A. FIG. 19 shows cross-sectional structures of the display portion 481, the driver circuit portion 482, the region including the FPC 473, the region including the FPC 450, and the like. Furthermore, FIG. 19 illustrates a cross-sectional structure of an intersection portion 487 where a wiring formed by processing a conductive layer used for forming the gate of the transistor and a wiring formed by processing a conductive layer used for forming the source and the drain of the transistor cross each other.

The substrate 471 and the substrate 472 are bonded to each other by the adhesive layer 417.

On the substrate 471 side, the structures of the transistor 401, the transistor 402, the transistor 403, the insulating layer 414, the insulating layer 415, and the capacitor 405 are different from the structures thereof in the display device shown in FIG. 14.

FIG. 19 illustrates top-gate transistors.

Each transistor includes a gate, the insulating layer 411, a semiconductor layer, a source, and a drain. The gate and the semiconductor layer overlap with each other with the insulating layer 411 provided therebetween. The semiconductor layer may include low-resistance regions 448. The low-resistance regions 448 function as the source and drain of the transistor.

The conductive layer over the insulating layer 413 functions as a lead wiring. The conductive layer is electrically connected to the region 448 through an opening provided in the insulating layer 413, the insulating layer 412, and the insulating layer 411.

In FIG. 19, the capacitor 405 has a stacked-layer structure that includes a layer formed by processing a semiconductor layer used for forming the above-described semiconductor layer, the insulating layer 411, and a layer formed by processing a conductive layer used for forming the gate. Here, part of the semiconductor layer of the capacitor 405 preferably has a region 449 having a higher conductivity than a region 447 where the channel of the transistor is formed.

The region 448 and the region 449 each can be a region containing more impurities than the region 447 where the channel of the transistor is formed, a region with a high carrier concentration, a region with low crystallinity, or the like.

Each of the transistors illustrated in FIG. 19 can have a structure in which the semiconductor layer is sandwiched between two gates.

The insulating layer 414 and the insulating layer 415 include an opening that reaches the insulating layer 413.

The adhesive layer 465, the insulating layer 461, the light-blocking layer 426, an insulating layer 463, the electrodes 431 and 432, an insulating layer 464, the insulating layer 462, the barrier layer 460, and the coloring layer 425 are stacked in this order on the substrate 471 side of the substrate 472.

The electrode 431 and the electrode 432 are provided on the substrate 471 side of the insulating layer 463. Here, an example where the electrode 431 includes an electrode 433 and an electrode 434 is described. As in the intersection portion 487 illustrated in FIG. 19, the electrode 432 and the electrode 433 are formed on the same plane. The insulating layer 464 is provided so as to cover the electrode 432 and the electrode 433. The electrode 434 is electrically connected to two electrodes 433 between which the electrode 432 is sandwiched, through openings provided in the insulating layer 464.

In the example described here, the electrode 433 is provided with an opening. The electrode 433 has a mesh-like or lattice-like top surface shape, for example. The electrode 433 is provided such that the opening overlaps with the coloring layer 425 and the light-emitting element 404. Furthermore, the electrode 433 is provided to overlap with the light-blocking layer 426. In this structure, a material that blocks visible light can be used as the electrode 433, so that a low-resistance material can be selected. Thus, sensing is possible with high sensitivity even when the area of the display portion is increased. Note that the electrode 432 and the electrode 434 can also have structures similar to the structure of the electrode 433, though only the electrode 433 is shown in FIG. 19.

With such a structure, the light-blocking layer 426 provided in a position closer to the substrate 472 than the electrodes and the like of the touch sensor can prevent the electrodes and the like from being seen by a user. Thus, a touch panel with not only a small thickness but also improved display quality can be achieved.

A connection portion 408 is provided in a region near an end portion of the substrate 472. The connection portion 408 has a stack including a wiring 442 and a conductive layer obtained by processing the same conductive layer as the electrode 434. The connection portion 408 is electrically connected to the FPC 450 through a connection layer 409.

### Structure Example 2 of Touch Panel

### Structure Example

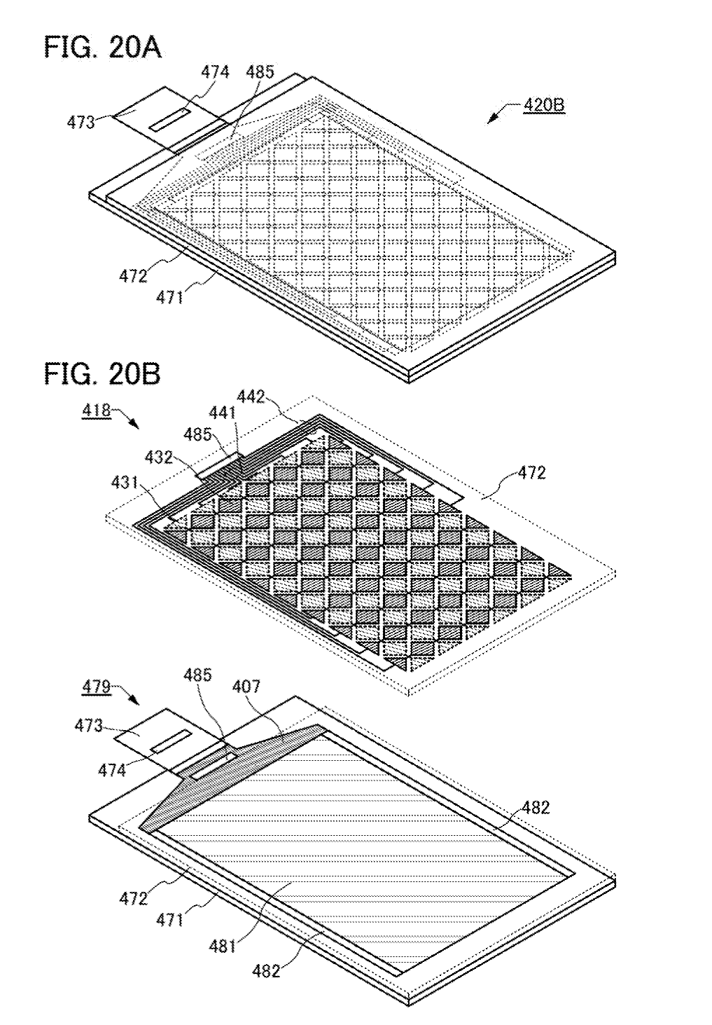

FIGS. 20A and 20B are schematic perspective views of a touch panel 420B.

The touch panel 420B includes a touch sensor and the light-emitting element 404 between a pair of flexible substrates (the substrate 471 and the substrate 472). When two flexible substrates are used, the touch panel can be thin, lightweight, and flexible. In FIGS. 20A and 20B, an input device 418 is provided for the substrate 472 included in the display device 479. The wiring 441, the wiring 442, and the like of the input device 418 are electrically connected to the FPC 473 provided for the display device 479.

With the above structure, the FPC connected to the touch panel 420B can be provided only on one substrate side (on the substrate 471 side in this embodiment).

Although two or more FPCs may be attached to the touch panel 420B, it is preferable that the touch panel 420B be provided with one FPC 473 and signals be supplied from the FPC 473 to both the display device 479 and the input device 418 as illustrated in FIGS. 20A and 20B, for the simplicity of the structure.

The IC 474 can have a function of driving the input device 418. Alternatively, an IC for driving the input device 418 may further be provided. Further alternatively, an IC for driving the input device 418 may be mounted on the substrate 471. The touch panel 420B shown in FIG. 20A can also be referred to as a touch panel module because the FPC 473 and the IC 474 are mounted.

### Cross-Sectional Structure Example

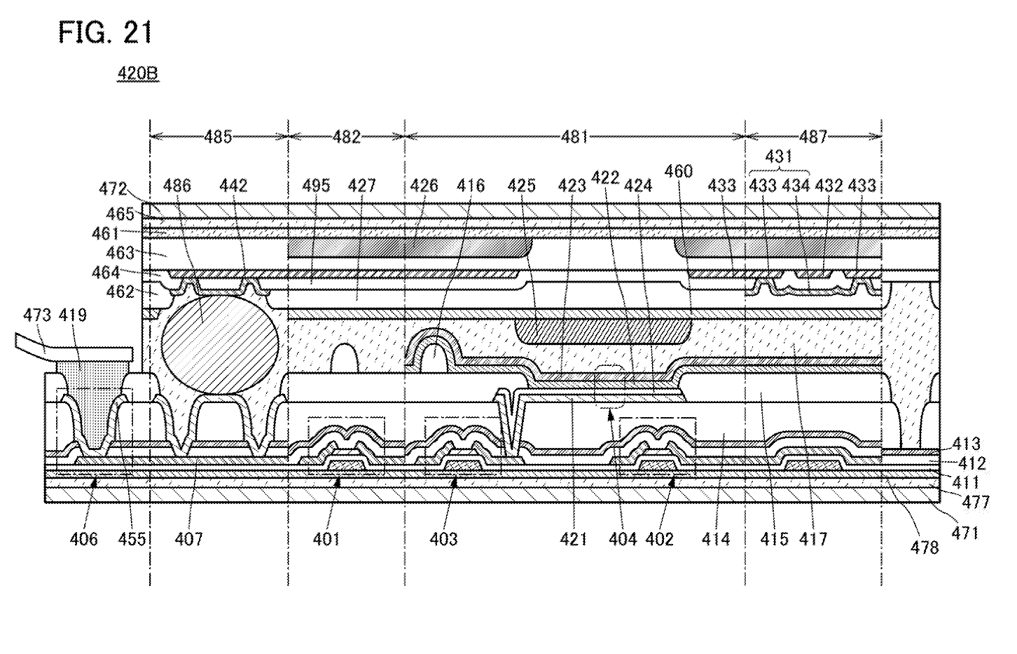

FIG. 21 is a cross-sectional view illustrating a region including the FPC 473, a connection portion 485, the driver circuit portion 482, and the display portion 481 in FIGS. 20A and 20B.

In the connection portion 485, one of the wirings 442 (or the wirings 441) and one of the wirings 407 are electrically connected to each other through a connector 486.

As the connector 486, a conductive particle can be used, for example.

The connector 486 is preferably provided so as to be covered with the adhesive layer 417. For example, the connectors 486 are dispersed in the adhesive layer 417 before curing of the adhesive layer 417. A structure in which the connection portion 485 is provided in a portion where the adhesive layer 417 is provided can be similarly applied not only to a structure in which the adhesive layer 417 is also provided over the light-emitting element 404 as illustrated in FIG. 21 (also referred to as a solid sealing structure) but also to, for example, a hollow sealing structure in which the adhesive layer 417 is provided in the periphery of a light-emitting device, a liquid crystal display device, or the like.

FIG. 21 illustrates an example in which the optical adjustment layer 424 does not cover an end portion of the electrode 421. In the example in FIG. 21, the spacer 416 is also provided in the driver circuit portion 482.

In addition to the light-blocking layer between the insulating layer 461 and the insulating layer 463, another light-blocking layer may be provided on the same plane as the coloring layer 425. In that case, light leakage can be inhibited more surely.

### Driving Method Example of Touch Sensor

An example of a driving method of an input device (touch sensor) which can be applied to the display device of one embodiment of the present invention will be described below.

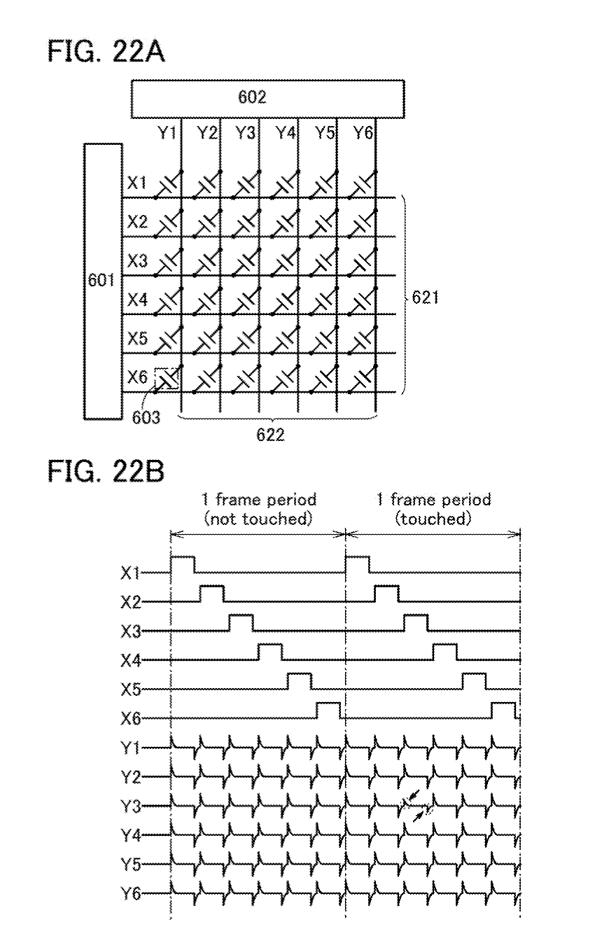

FIG. 22A is a block diagram illustrating the structure of a mutual capacitive touch sensor. FIG. 22A illustrates a pulse voltage output circuit 601 and a current sensing circuit 602. Note that in FIG. 22A, six wirings X1 to X6 represent electrodes 621 to which a pulse voltage is applied, and six wirings Y1 to Y6 represent electrodes 622 that sense changes in current. The number of such electrodes is not limited to those illustrated in this example. FIG. 22A also illustrates a capacitor 603 that is formed with the electrodes 621 and 622 overlapping with each other or being provided close to each other. Note that functional replacement between the electrodes 621 and 622 is possible.

For example, the conductive layer 551 corresponds to one of the electrodes 621 and 622, and the conductive layer 552 corresponds to the other of the electrodes 621 and 622.

The pulse voltage output circuit 601 is, for example, a circuit for sequentially inputting a pulse voltage to the wirings X1 to X6. The current sensing circuit 602 is, for example, a circuit for sensing current flowing through each of the wirings Y1 to Y6.

By application of a pulse voltage to one of the wirings X1 to X6, an electric field is generated between the electrodes 621 and 622 of the capacitor 603, and current flows through the electrode 622. Part of the electric field generated between the electrodes is blocked when an object such a finger or a stylus contacts or approaches the device, so that the electric field intensity between the electrodes is changed. Consequently, the amount of current flowing through the electrode 622 is changed.

For example, in the case where there is no approach or no contact of an object, the amount of current flowing in each of the wirings Y1 to Y6 depends on the amount of capacitance of the capacitor 603. In the case where part of an electric field is blocked by the approach or contact of an object, a decrease in the amount of current flowing in the wirings Y1 to Y6 is sensed. The approach or contact of an object can be sensed by utilizing this change.

Sensing by the current sensing circuit 602 may be performed using an integral value (time integral value) of current flowing in a wiring. In that case, sensing may be performed with an integrator circuit, for example. Alternatively, the peak current value may be sensed. In that case, for example, current may be converted into voltage, and the peak voltage value may be sensed.

FIG. 22B is an example of a timing chart illustrating input and output waveforms in the mutual capacitive touch sensor in FIG. 22A. In FIG. 22B, sensing in each row and each column is performed in one sensing period. FIG. 22B shows a period when the contact or approach of an object is not sensed (when the touch sensor is not touched) and a period when the contact or approach of an object is sensed (when the touch sensor is touched). Here, the wirings Y1 to Y6 each show a waveform of a voltage corresponding to the amount of current to be sensed.

As shown in FIG. 22B, the wirings X1 to X6 are sequentially supplied with a pulse voltage. Accordingly, current flows in the wirings Y1 to Y6. When the touch sensor is not touched, substantially the same current flows in the wirings Y1 to Y6 in accordance with a change in voltages of the wirings X1 to X6; thus, the wirings Y1 to Y6 have similar output waveforms. Meanwhile, when the touch sensor is touched, current flowing in a wiring in a position which an object contacts or approaches among the wirings Y1 to Y6 is reduced; thus, the output waveforms are changed as shown in FIG. 22B.

FIG. 22B shows an example in which an object contacts or approaches the intersection of the wiring X3 and the wiring Y3 or the vicinity thereof

A change in current due to block of an electric field generated between a pair of electrodes is sensed in this manner in a mutual capacitive touch sensor, so that positional information of an object can be obtained. When the detection sensitivity is high, the coordinates of the object can be determined even when the object is far from a detection surface (e.g., a surface of the touch panel).

By driving a touch panel by a method in which a display period of a display portion and a sensing period of a touch sensor do not overlap with each other, the detection sensitivity of the touch sensor can be increased. For example, a display period and a sensing period may be separately provided in one display frame period. In that case, two or more sensing periods are preferably provided in one frame period. When the frequency of sensing is increased, the detection sensitivity can be increased.

It is preferable that, as an example, the pulse voltage output circuit 601 and the current sensing circuit 602 be formed in an IC chip. For example, the IC chip is preferably mounted on a touch panel or a substrate in a housing of an electronic device. In the case where the touch panel has flexibility, parasitic capacitance might be increased in a bent portion of the touch panel, and the influence of noise might be increased. In view of this, it is preferable to use an IC to which a driving method less influenced by noise is applied. For example, it is preferable to use an IC to which a driving method capable of increasing a signal-noise ratio (S/N ratio) is applied.

At least part of this embodiment can be implemented in combination with any of the other embodiments described in this specification as appropriate.

### Embodiment 4

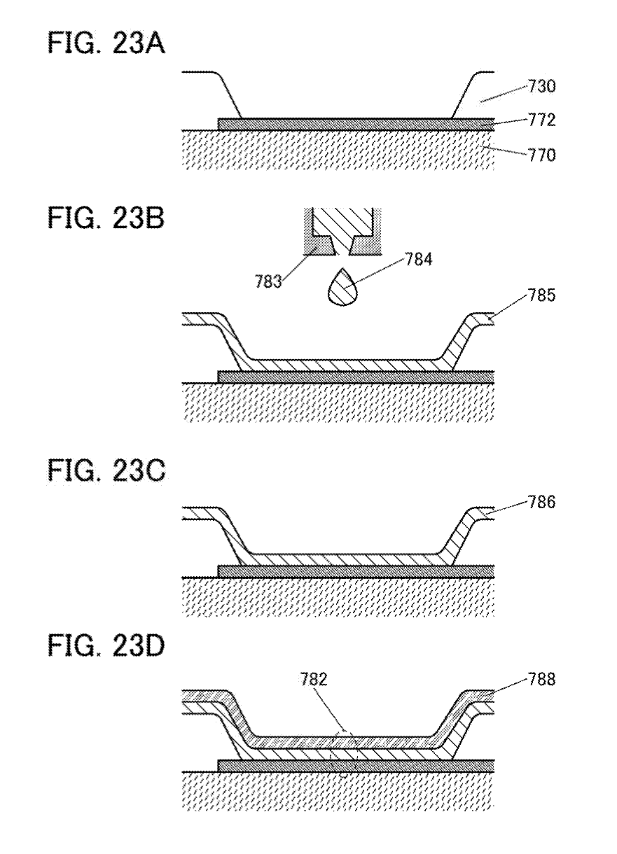

In this embodiment, a method for forming an EL layer by a droplet discharge method will be described with reference to FIGS. 23A to 23D. FIGS. 23A to 23D are cross-sectional views illustrating the method for forming an EL layer 786.

First, a conductive film 772 is formed over a planarization insulating film 770, and an insulating film 730 is formed to cover part of the conductive film 772 (see FIG. 23A).

Then, a droplet 784 is discharged to an exposed portion of the conductive film 772, which is an opening of the insulating film 730, from a droplet discharge apparatus 783, so that a composition containing layer 785 is formed. The droplet 784 is a composition containing a solvent and is attached to the conductive film 772 (see FIG. 23B).

Note that the step of discharging the droplet 784 may be performed under reduced pressure.

Next, the solvent is removed from the composition containing layer 785, and the resulting layer is solidified to form the EL layer 786 (see FIG. 23C).

The solvent may be removed by drying or heating.

Next, a conductive film 788 is formed over the EL layer 786; thus, a light-emitting element 782 is completed (see FIG. 23D).

When the EL layer 786 is formed by a droplet discharge method as described above, the composition can be selectively discharged; accordingly, waste of material can be reduced. Furthermore, a lithography process or the like for shaping is not needed, and thus, the process can be simplified and cost reduction can be achieved.

The droplet discharge method described above is a general term for a means including a nozzle equipped with a composition discharge opening or a means to discharge droplets such as a head having one or a plurality of nozzles.

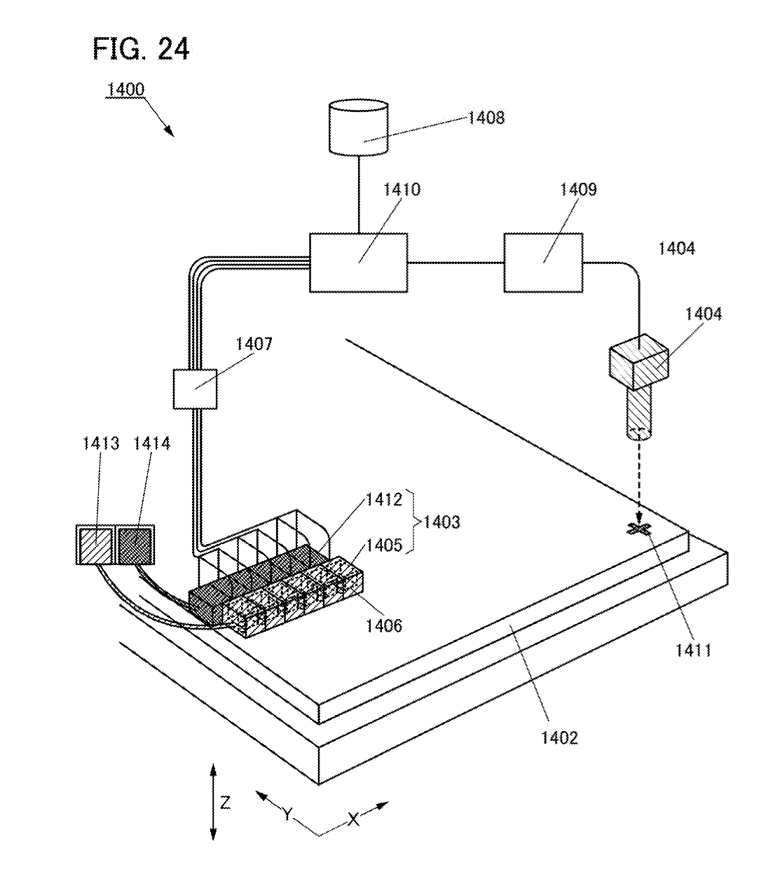

Next, a droplet discharge apparatus used for the droplet discharge method is described with reference to FIG. 24. FIG. 24 is a conceptual diagram illustrating a droplet discharge apparatus 1400.

The droplet discharge apparatus 1400 includes a droplet discharge means 1403. In addition, the droplet discharge means 1403 is equipped with a head 1405 and a head 1412.

The heads 1405 and 1412 are connected to a control means 1407, and this control means 1407 is controlled by a computer 1410; thus, a preprogrammed pattern can be drawn.

The drawing may be conducted at a timing, for example, based on a marker 1411 formed over a substrate 1402. Alternatively, the reference point may be determined on the basis of an outer edge of the substrate 1402. Here, the marker 1411 is detected by an imaging means 1404 and converted into a digital signal by an image processing means 1409. Then, the digital signal is recognized by the computer 1410, and then, a control signal is generated and transmitted to the control means 1407.

An image sensor or the like using a charge coupled device (CCD) or a complementary metal oxide semiconductor (CMOS) can be used as the imaging means 1404. Note that information about a pattern to be formed over the substrate 1402 is stored in a storage medium 1408, and a control signal is transmitted to the control means 1407 based on the information, so that each of the heads 1405 and 1412 of the droplet discharge means 1403 can be individually controlled. The heads 1405 and 1412 are supplied with a material to be discharged from material supply sources 1413 and 1414 through pipes, respectively.

Inside the head 1405, a space as indicated by a dotted line 1406 to be filled with a liquid material and a nozzle which is a discharge outlet are provided. Although it is not shown, an inside structure of the head 1412 is similar to that of the head 1405. When the nozzle sizes of the heads 1405 and 1412 are different from each other, different materials with different widths can be discharged simultaneously. Each head can discharge and draw a plurality of light emitting materials. In the case of drawing over a large area, the same material can be simultaneously discharged to be drawn from a plurality of nozzles in order to improve throughput. When a large substrate is used, the heads 1405 and 1412 can freely scan the substrate in directions indicated by arrows X, Y, and Z in FIG. 24, and a region in which a pattern is drawn can be freely set. Thus, a plurality of the same patterns can be drawn over one substrate.

Furthermore, a step of discharging the composition may be performed under reduced pressure. A substrate may be heated when the composition is discharged. After discharging the composition, either drying or baking or both of them are performed. Both the drying and baking are heat treatments but different in purpose, temperature, and time period. The steps of drying and baking are performed under normal pressure or under reduced pressure by laser irradiation, rapid thermal annealing, heating using a heating furnace, or the like. Note that there is no particular limitation on the timing of the heat treatment and the number of times of the heat treatment. The temperature for performing each of the steps of drying and baking in a favorable manner depends on the material of the substrate and the properties of the composition.

In the above-described manner, the EL layer 786 can be formed with the droplet discharge apparatus.

At least part of this embodiment can be implemented in combination with any of the other embodiments described in this specification as appropriate. cl Embodiment 5

In this embodiment, electronic devices and lighting devices of one embodiment of the present invention will be described with reference to drawings.

Electronic devices and lighting devices can be manufactured by using the display device of one embodiment of the present invention. Highly reliable electronic devices and lighting devices with curved surfaces can be manufactured by using the display device of one embodiment of the present invention. In addition, flexible and highly reliable electronic devices and lighting devices can be manufactured by using the display device of one embodiment of the present invention.

Examples of electronic devices include a television set, a desktop or notebook personal computer, a monitor of a computer or the like, a digital camera, a digital video camera, a digital photo frame, a mobile phone, a portable game machine, a portable information terminal, an audio reproducing device, and a large game machine such as a pachinko machine.

The electronic device or the lighting device of one embodiment of the present invention can be incorporated along a curved inside/outside wall surface of a house or a building or a curved interior/exterior surface of a car.

Furthermore, the electronic device of one embodiment of the present invention may include a secondary battery. Preferably, the secondary battery is capable of being charged by contactless power transmission.

Examples of the secondary battery include a lithium-ion secondary battery such as a lithium polymer battery (lithium ion polymer battery) using a gel electrolyte, a nickel-hydride battery, a nickel-cadmium battery, an organic radical battery, a lead-acid battery, an air secondary battery, a nickel-zinc battery, and a silver-zinc battery.

The electronic device of one embodiment of the present invention may include an antenna. When a signal is received by the antenna, an image, data, or the like can be displayed on a display portion. When the electronic device includes the antenna and a secondary battery, the antenna may be used for contactless power transmission.

The electronic device of one embodiment of the present invention may include a sensor (a sensor having a function of measuring force, displacement, position, speed, acceleration, angular velocity, rotational frequency, distance, light, liquid, magnetism, temperature, chemical substance, sound, time, hardness, electric field, current, voltage, electric power, radiation, flow rate, humidity, gradient, oscillation, odor, or infrared rays).

The electronic device of one embodiment of the present invention can have a variety of functions, for example, a function of displaying a variety of information (e.g., a still image, a moving image, and a text image) on a display portion, a touch panel function, a function of displaying a calendar, date, time, and the like, a function of executing a variety of software (programs), a wireless communication function, and a function of reading a program or data stored in a recording medium.

Furthermore, the electronic device including a plurality of display portions can have a function of displaying image information mainly on one display portion while displaying text information mainly on another display portion, a function of displaying a three-dimensional image by displaying images where parallax is considered on a plurality of display portions, or the like. Furthermore, the electronic device including an image receiving portion can have a function of taking a still image or a moving image, a function of automatically or manually correcting a photographed image, a function of storing a photographed image in a recording medium (an external recording medium or a recording medium incorporated in the electronic device), a function of displaying a photographed image on a display portion, or the like. Note that the functions of the electronic device of one embodiment of the present invention are not limited thereto, and the electronic devices can have a variety of functions.

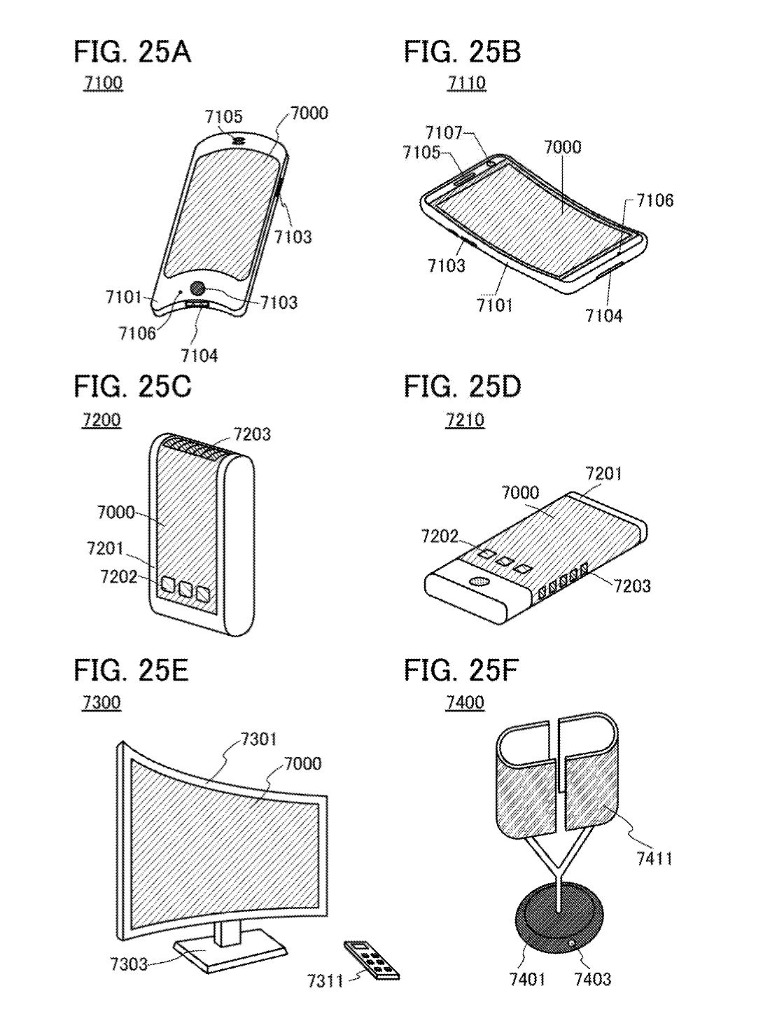

FIGS. 25A to 25E illustrate examples of an electronic device including a display portion 7000 with a curved surface. The display surface of the display portion 7000 is bent, and images can be displayed on the bent display surface. The display portion 7000 may have flexibility.

The display portion 7000 can be formed using the display device or the like of one embodiment of the present invention. One embodiment of the present invention makes it possible to provide a highly reliable electronic device having a curved display portion.

FIGS. 25A and 25B illustrate examples of mobile phones. A mobile phone 7100 illustrated in FIG. 25A and a mobile phone 7110 illustrated in FIG. 25B each include a housing 7101, the display portion 7000, operation buttons 7103, an external connection port 7104, a speaker 7105, a microphone 7106, and the like. The mobile phone 7110 illustrated in FIG. 25B also includes a camera 7107.

Each mobile phone includes a touch sensor in the display portion 7000. Operations such as making a call and inputting text can be performed by touch on the display portion 7000 with a finger, a stylus, or the like.

With the operation buttons 7103, power can be on or off. In addition, types of images displayed on the display portion 7000 can be switched; for example, switching from a mail creation screen to a main menu screen can be performed.

When a detection device such as a gyroscope or an acceleration sensor is provided inside the mobile phone, the direction of display on the screen of the display portion 7000 can be automatically changed by determining the orientation of the mobile phone (whether the mobile phone is placed horizontally or vertically). Furthermore, the direction of display on the screen can be changed by touch on the display portion 7000, operation with the operation button 7103, sound input using the microphone 7106, or the like.

FIGS. 25C and 25D illustrate examples of portable information terminals. A portable information terminal 7200 illustrated in FIG. 25C and a portable information terminal 7210 illustrated in FIG. 25D each include a housing 7201 and the display portion 7000. Each of the portable information terminals may also include an operation button, an external connection port, a speaker, a microphone, an antenna, a camera, a battery, or the like. The display portion 7000 is provided with a touch sensor. The operation of the portable information terminal can be performed by touching the display portion 7000 with a finger, a stylus, or the like.

Each of the portable information terminals illustrated in this embodiment functions as, for example, one or more of a telephone set, a notebook, and an information browsing system. Specifically, the portable information terminals each can be used as a smartphone. Each of the portable information terminals illustrated in this embodiment is capable of executing, for example, a variety of applications such as mobile phone calls, e-mailing, reading and editing texts, music reproduction, Internet communication, and a computer game.

The portable information terminals 7200 and 7210 can display characters, image information, and the like on its plurality of surfaces. For example, as illustrated in FIGS. 25C and 25D, three operation buttons 7202 can be displayed on one surface, and information 7203 indicated by a rectangle can be displayed on another surface. FIG. 25C illustrates an example in which information is displayed at the top of the portable information terminal. FIG. 25D illustrates an example in which information is displayed on the side of the portable information terminal. Information may be displayed on three or more surfaces of the portable information terminal.

Examples of the information include notification from a social networking service (SNS), display indicating reception of an e-mail or an incoming call, the title of an e-mail or the like, the sender of an e-mail or the like, the date, the time, remaining battery, and the reception strength of an antenna. Alternatively, the operation button, an icon, or the like may be displayed instead of the information.

For example, a user of the portable information terminal 7200 can see the display (here, the information 7203) on the portable information terminal 7200 put in a breast pocket of his/her clothes.

Specifically, a caller's phone number, name, or the like of an incoming call is displayed in a position that can be seen from above the portable information terminal 7200. Thus, the user can see the display without taking out the portable information terminal 7200 from the pocket and decide whether to answer the call.

FIG. 25E illustrates an example of a television set. In a television set 7300, the display portion 7000 is incorporated into a housing 7301. Here, the housing 7301 is supported by a stand 7303.

The television set 7300 illustrated in FIG. 25E can be operated with an operation switch of the housing 7301 or a separate remote controller 7311. The display portion 7000 may include a touch sensor, and can be operated by touch on the display portion 7000 with a finger or the like. The remote controller 7311 may be provided with a display portion for displaying data output from the remote controller 7311. With operation keys or a touch panel of the remote controller 7311, channels and volume can be controlled and images displayed on the display portion 7000 can be controlled.

Note that the television set 7300 is provided with a receiver, a modem, and the like. A general television broadcast can be received with the receiver. When the television set is connected to a communication network with or without wires via the modem, one-way (from a transmitter to a receiver) or two-way (between a transmitter and a receiver or between receivers) data communication can be performed.

FIG. 25F illustrates an example of a lighting device having a curved light-emitting portion.

The light-emitting portion included in the lighting device illustrated in FIG. 25F can be manufactured using the display device or the like of one embodiment of the present invention. According to one embodiment of the present invention, a highly reliable lighting device having a curved light-emitting portion can be provided.

A light-emitting portion 7411 included in a lighting device 7400 illustrated in FIG. 25F has two convex-curved light-emitting portions symmetrically placed. Thus, all directions can be illuminated with the lighting device 7400 as a center.

The light-emitting portion included in the lighting device 7400 may have flexibility. The light-emitting portion may be fixed on a plastic member, a movable frame, or the like so that a light-emitting surface of the light-emitting portion can be bent freely depending on the intended use.

The lighting device 7400 includes a stage 7401 provided with an operation switch 7403 and the light-emitting portion supported by the stage 7401.

Note that although the lighting device in which the light-emitting portion is supported by the stage is described as an example here, a housing provided with a light-emitting portion can be fixed on a ceiling or suspended from a ceiling. Since the light-emitting surface can be curved, the light-emitting surface is curved to have a concave shape, whereby a particular region can be brightly illuminated, or the light-emitting surface is curved to have a convex shape, whereby a whole room can be brightly illuminated.

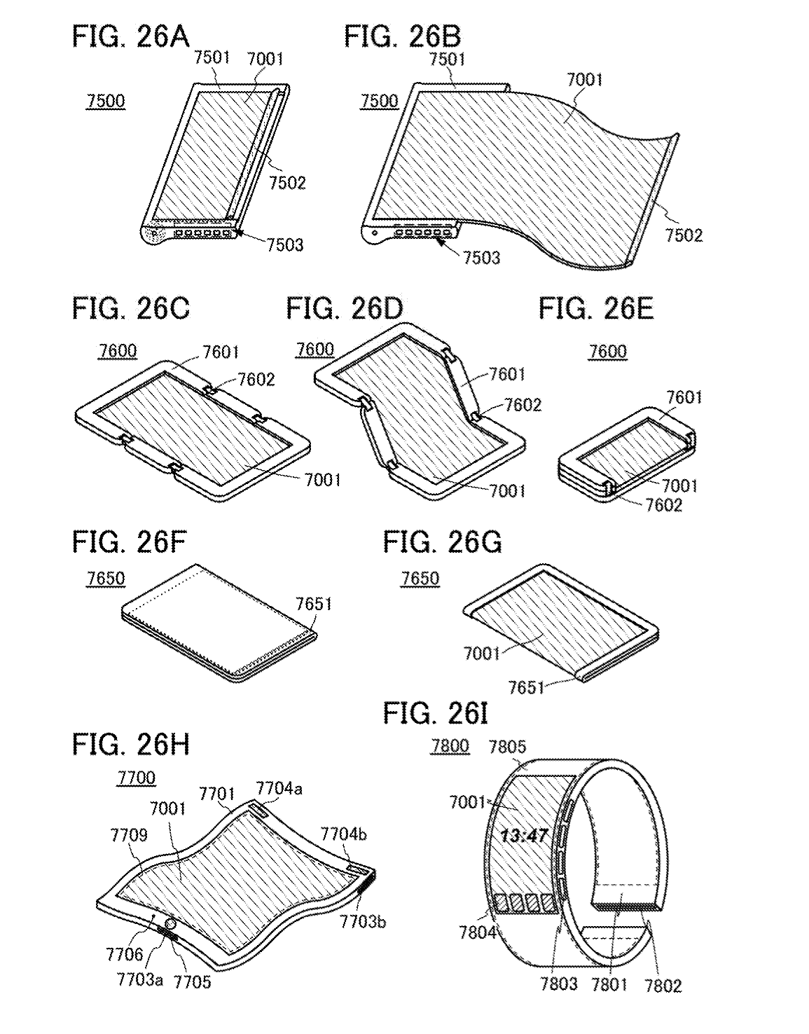

FIGS. 26A to 26I each illustrate an example of a portable information terminal including a flexible and bendable display portion 7001.

The display portion 7001 is manufactured using the display device or the like of one embodiment of the present invention. For example, a display device that can be bent with a radius of curvature of greater than or equal to 0.01 mm and less than or equal to 150 mm can be used. The display portion 7001 may include a touch sensor so that the portable information terminal can be operated by touch on the display portion 7001 with a finger or the like. One embodiment of the present invention makes it possible to provide a highly reliable electronic device including a display portion having flexibility.

FIGS. 26A and 26B are perspective views illustrating an example of the portable information terminal. A portable information terminal 7500 includes a housing 7501, the display portion 7001, a display portion tab 7502, operation buttons 7503, and the like.

The portable information terminal 7500 includes a rolled flexible display portion 7001 in the housing 7501. The display portion 7001 can be pulled out by using the display portion tab 7502.

The portable information terminal 7500 can receive a video signal with a control portion incorporated therein and can display the received image on the display portion 7001. The portable information terminal 7500 incorporates a battery. A terminal portion for connecting a connector may be included in the housing 7501 so that a video signal or power can be directly supplied from the outside with a wiring.

With the operation buttons 7503, turning on or off of the power, switching of displayed images, and the like can be performed. Although FIGS. 26A and 26B show an example in which the operation buttons 7503 are positioned on a side surface of the portable information terminal 7500, one embodiment of the present invention is not limited thereto. The operation buttons 7503 may be placed on a display surface (a front surface) or a rear surface of the portable information terminal 7500.

FIG. 26B illustrates the portable information terminal 7500 in a state where the display portion 7001 is pulled out. Images can be displayed on the display portion 7001 in this state. In addition, the portable information terminal 7500 may perform different displays in the state where part of the display portion 7001 is rolled as shown in FIG. 26A and in the state where the display portion 7001 is pulled out as illustrated in FIG. 26B. For example, in the state shown in FIG. 26A, the rolled portion of the display portion 7001 is put in a non-display state, reducing the power consumption of the portable information terminal 7500.

Note that a reinforcement frame may be provided for a side portion of the display portion 7001 so that the display portion 7001 has a flat display surface when pulled out.

Note that in addition to this structure, a speaker may be provided for the housing so that sound is output with an audio signal received together with a video signal.

FIGS. 26C to 26E illustrate an example of a foldable portable information terminal. FIG. 26C illustrates a portable information terminal 7600 that is opened. FIG. 26D illustrates the portable information terminal 7600 that is being opened or being folded. FIG. 26E illustrates the portable information terminal 7600 that is folded. The portable information terminal 7600 is highly portable when folded, and is highly browsable when opened because of a seamless large display area.

The display portion 7001 is supported by three housings 7601 joined together by hinges 7602. By folding the portable information terminal 7600 at a connection portion between two housings 7601 with the hinges 7602, the portable information terminal 7600 can be reversibly changed in shape from an opened state to a folded state.

FIGS. 26F and 26G illustrate an example of a foldable portable information terminal. FIG. 26F illustrates a portable information terminal 7650 that is folded so that the display portion 7001 is on the inside. FIG. 26G illustrates the portable information terminal 7650 that is folded so that the display portion 7001 is on the outside. The portable information terminal 7650 includes the display portion 7001 and a non-display portion 7651. When the portable information terminal 7650 is not used, the portable information terminal 7650 is folded so that the display portion 7001 is on the inside, whereby the display portion 7001 can be prevented from being contaminated or damaged.

FIG. 26H illustrates an example of a flexible portable information terminal. A portable information terminal 7700 includes a housing 7701 and the display portion 7001. The portable information terminal 7700 may further include buttons 7703a and 7703b which serve as input means, speakers 7704a and 7704b which serve as sound output means, an external connection port 7705, a microphone 7706, or the like. A flexible battery 7709 can be included in the portable information terminal 7700. The battery 7709 may be arranged to overlap with the display portion 7001, for example.

The housing 7701, the display portion 7001, and the battery 7709 have flexibility. Thus, it is easy to curve the portable information terminal 7700 into a desired shape or to twist the portable information terminal 7700. For example, the portable information terminal 7700 can be folded so that the display portion 7001 is on the inside or on the outside. The portable information terminal 7700 can be used in a rolled state. Since the housing 7701 and the display portion 7001 can be transformed freely in this manner, the portable information terminal 7700 is less likely to be broken even when the portable information terminal 7700 falls down or external stress is applied to the portable information terminal 7700.

The portable information terminal 7700 is lightweight and therefore can be used conveniently in various situations. For example, the portable information terminal 7700 can be used in the state where the upper portion of the housing 7701 is suspended by a clip or the like, or in the state where the housing 7701 is fixed to a wall by magnets or the like.

FIG. 26I illustrates an example of a wrist-watch-type portable information terminal. The portable information terminal 7800 includes a band 7801, the display portion 7001, an input/output terminal 7802, operation buttons 7803, and the like. The band 7801 functions as a housing. A flexible battery 7805 can be included in the portable information terminal 7800. The battery 7805 may be arranged to overlap with the display portion 7001, or the band 7801 and the like, for example.

The band 7801, the display portion 7001, and the battery 7805 have flexibility. Thus, the portable information terminal 7800 can be easily curved to have a desired shape.

With the operation buttons 7803, a variety of functions such as time setting, turning on or off of the power, turning on or off of wireless communication, setting and cancellation of silent mode, and setting and cancellation of power saving mode can be performed. For example, the functions of the operation buttons 7803 can be set freely by the operating system incorporated in the portable information terminal 7800.

By touch on an icon 7804 displayed on the display portion 7001 with a finger or the like, application can be started.

The portable information terminal 7800 can employ near field communication conformable to a communication standard. For example, mutual communication between the portable information terminal and a headset capable of wireless communication can be performed, and thus hands-free calling is possible.

The portable information terminal 7800 may include the input/output terminal 7802. In the case where the input/output terminal 7802 is included in the portable information terminal 7800, data can be directly transmitted to and received from another information terminal via a connector. Charging through the input/output terminal 7802 is also possible. Note that charging of the portable information terminal described as an example in this embodiment can be performed by contactless power transmission without using the input/output terminal.

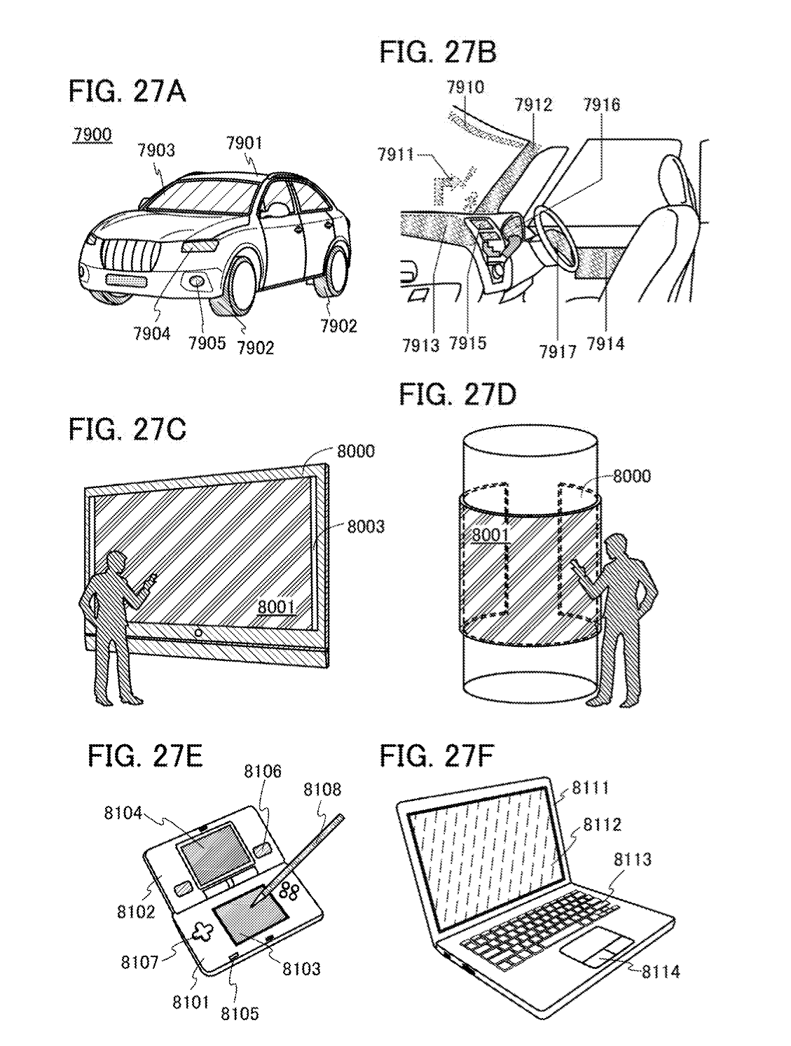

FIG. 27A is an external view of an automobile 7900. FIG. 27B illustrates a driver's seat of the automobile 7900. The automobile 7900 includes a car body 7901, wheels 7902, a windshield 7903, lights 7904, fog lamps 7905, and the like.

The display device of one embodiment of the present invention can be used in a display portion of the automobile 7900. For example, the display device of one embodiment of the present invention can be used in display portions 7910 to 7917 illustrated in FIG. 27B.

The display portion 7910 and the display portion 7911 are provided in the automobile windshield. The display device of one embodiment of the present invention can be a see-through device, through which the opposite side can be seen, by using a light-transmitting conductive material for its electrodes. Such a see-through display device does not hinder driver's vision during the driving of the automobile 7900. Therefore, the display device of one embodiment of the present invention can be provided in the windshield of the automobile 7900. Note that in the case where a transistor or the like is provided in the display device, a transistor having light-transmitting properties, such as an organic transistor using an organic semiconductor material or a transistor using an oxide semiconductor, is preferably used.

A display portion 7912 is provided on a pillar portion. A display portion 7913 is provided on a dashboard. For example, the display portion 7912 can compensate for the view hindered by the pillar portion by showing an image taken by an imaging means provided on the car body. Similarly, the display portion 7913 can compensate for the view hindered by the dashboard and a display portion 7914 can compensate for the view hindered by the door. That is, showing a video taken by an imaging means provided on the outside of the automobile leads to elimination of blind areas and enhancement of safety. In addition, showing a video so as to compensate for the area which a driver cannot see makes it possible for the driver to confirm safety easily and comfortably.

The display portion 7917 is provided in a steering wheel. The display portion 7915, the display portion 7916, or the display portion 7917 can display a variety of kinds of information such as navigation information, a speedometer, a tachometer, a mileage, a fuel meter, a gearshift indicator, and air-condition setting. The content, layout, or the like of the display on the display portions can be customized freely by a user as appropriate. The information listed above can also be displayed on the display portions 7910 to 7914.

The display portions 7910 to 7917 can also be used as lighting devices.

A display portion included in the display device of one embodiment of the present invention may have a flat surface. In that case, the display device of one embodiment of the present invention does not necessarily have a curved surface and flexibility.

FIGS. 27C and 27D each illustrate an example of digital signage including a housing 8000, a display portion 8001, a speaker 8003, and the like. An LED lamp, operation keys (including a power switch or an operation switch), a connection terminal, a variety of sensors, a microphone, and the like may also be included.

FIG. 27D illustrates a digital signage mounted on a cylindrical pillar.

A larger display portion 8001 can provide more information at a time. In addition, a larger display portion 8001 attracts more attention, so that the effectiveness of the advertisement is expected to be increased, for example.

It is preferable to use a touch panel in the display portion 8001 because a device with such a structure does not just display a still or moving image, but can be operated by users intuitively. Alternatively, in the case where the device is used to provide information such as route information or traffic information, usability can be enhanced by intuitive operation.

FIG. 27E illustrates a portable game console including a housing 8101, a housing 8102, a display portion 8103, a display portion 8104, a microphone 8105, a speaker 8106, an operation key 8107, a stylus 8108, and the like.

The portable game console illustrated in FIG. 27E includes two display portions 8103 and 8104. Note that the number of display portions of the electronic device of one embodiment of the present invention is not limited to two and can be one or three or more as long as at least one display portion includes the display device of one embodiment of the present invention.

FIG. 27F illustrates a notebook personal computer which includes a housing 8111, a display portion 8112, a keyboard 8113, a pointing device 8114, and the like. The display device of one embodiment of the present invention can be used for the display portion 8112.

At least part of this embodiment can be implemented in combination with any of the other embodiments described in this specification as appropriate.

This application is based on Japanese Patent Application serial no. 2016-013331 filed with Japan Patent Office on Jan. 27, 2016, the entire contents of which are hereby incorporated by reference.

What is claimed is:

1. A display device comprising:
a first substrate;
a second substrate;
a display element;
a light-blocking layer;
a first barrier layer; and
an adhesive layer,
wherein the first substrate and the second substrate are positioned to face each other,
wherein the display element, the light-blocking layer, the first barrier layer, and the adhesive layer are between the first substrate and the second substrate,
wherein the display element is between the first substrate and the adhesive layer,
wherein the light-blocking layer is between the second substrate and the adhesive layer, and
wherein the first barrier layer includes a region between the light-blocking layer and the adhesive layer.

2. The display device according to claim 1,
wherein the first barrier layer includes a material having a higher Young's modulus than at least one of the light-blocking layer and the adhesive layer.

3. The display device according to claim 1, further comprising a second barrier layer,
wherein the second barrier layer includes a region between the first substrate and the display element, and
wherein the second barrier layer includes a material having a higher Young's modulus than the light-blocking layer.

4. The display device according to claim 1,
wherein the first barrier layer includes at least one of a silicon oxide, a silicon oxynitride, a silicon nitride oxide, a silicon nitride, an aluminum oxide, and an aluminum nitride.

5. The display device according to claim 4,
wherein two or more insulating films are stacked in the first barrier layer.

6. The display device according to claim 1, further comprising a transistor,
wherein the transistor is between the first substrate and the adhesive layer.

7. The display device according to claim 1, further comprising a conductive layer,
wherein the conductive layer is between the first barrier layer and the second substrate, and
wherein the conductive layer has an island-like top surface shape.

8. The display device according to claim 7,
wherein the conductive layer includes a metal oxide.

9. The display device according to claim 7,
wherein the conductive layer includes a metal or an alloy, and
wherein the conductive layer has a mesh-like top surface shape.

10. The display device according to claim 7,
wherein the conductive layer includes a region between the light-blocking layer and the first barrier layer and a region overlapping with the light-blocking layer.

11. A display device comprising:
a first substrate;
a second substrate;
a display element;
a light-blocking layer;
a coloring layer;
a first barrier layer; and
an adhesive layer,
wherein the first substrate and the second substrate are positioned to face each other,
wherein the display element, the light-blocking layer, the first barrier layer, the coloring layer, and the adhesive layer are between the first substrate and the second substrate,
wherein the display element is between the first substrate and the adhesive layer,
wherein the light-blocking layer and the coloring layer are between the second substrate and the adhesive layer, and
wherein the first barrier layer includes a region between the light-blocking layer and the coloring layer.

12. The display device according to claim 11,
wherein the light-blocking layer is between the first barrier layer and the second substrate, and
wherein the coloring layer is between the first barrier layer and the adhesive layer.

13. The display device according to claim 11,
wherein the first barrier layer includes a material having a higher Young's modulus than at least one of the light-blocking layer and the adhesive layer.

14. The display device according to claim 11,
wherein each of the first substrate and the second substrate has flexibility and includes a material having a lower Young's modulus than the material included in the first barrier layer.

15. The display device according to claim 11, further comprising a second barrier layer,
wherein the second barrier layer includes a region between the first substrate and the display element, and
wherein the second barrier layer includes a material having a higher Young's modulus than the light-blocking layer.

16. The display device according to claim 11,
wherein the first barrier layer includes at least one of a silicon oxide, a silicon oxynitride, a silicon nitride oxide, a silicon nitride, an aluminum oxide, and an aluminum nitride.

17. The display device according to claim 16,
wherein two or more insulating films are stacked in the first barrier layer.

18. The display device according to claim 11, further comprising a transistor,
wherein the transistor is between the first substrate and the adhesive layer.

19. The display device according to claim 11, further comprising a conductive layer,
wherein the conductive layer is between the first barrier layer and the second substrate, and
wherein the conductive layer has an island-like top surface shape.

20. The display device according to claim 19,
wherein the conductive layer includes a metal oxide.

21. The display device according to claim 19,
wherein the conductive layer includes a metal or an alloy, and
wherein the conductive layer has a mesh-like top surface shape.

22. The display device according to claim 19,
wherein the conductive layer includes a region between the light-blocking layer and the first barrier layer and a region overlapping with the light-blocking layer.
